(19) United States
(12) Patent Application Publication
(10) Pub. No.: US 2026/0068246 A1
(43) Pub. Date: Mar. 5, 2026

(54) SEMICONDUCTOR DEVICE

(71) Applicant: Mitsubishi Electric Corporation, Tokyo (JP)

(72) Inventors: Yu SEIKOBA, Tokyo (JP); Kazuya HOKAZONO, Tokyo (JP)

(73) Assignee: Mitsubishi Electric Corporation, Tokyo (JP)

(21) Appl. No.: 19/247,905

(22) Filed: Jun. 24, 2025

(30) Foreign Application Priority Data
Sep. 5, 2024 (JP) 2024-153069

(51) Int. Cl. H10D 62/10; H10D 8/00; H10D 62/60; H10D 84/80

(52) U.S. Cl. CPC H10D 62/126; H10D 8/411; H10D 62/107; H10D 62/60; H10D 84/811

(57) ABSTRACT

A semiconductor device includes first and second N-type semiconductor regions provided selectively in an upper layer part of an N-type high-breakdown voltage isolation region, and a P-type semiconductor region provided selectively in the upper layer part of the N-type high-breakdown voltage isolation region and to be supplied with a first power supply voltage lower than a second power supply voltage. The second N-type semiconductor region is arranged closer to an N-type high-potential region than the first N-type semiconductor region and the P-type semiconductor region. The P-type semiconductor region is arranged between the first N-type semiconductor region and the second N-type high-potential region in a plan view. A diode has an anode to be supplied with the second power supply voltage, and a cathode electrically connected to the first N-type semiconductor region. The second N-type semiconductor region is electrically connected to the N-type high-potential region.

### BACKGROUND

### Technical Field

The present disclosure relates to a semiconductor device with an N-type high-potential region provided with a high-voltage side driving circuit.

### Description of the Background Art

As an example, a conventional semiconductor device with an N-type high-potential region provided with a high-voltage side driving circuit includes a semiconductor device disclosed in Japanese Patent Application Laid-Open No. 2004-47937.

In the semiconductor device disclosed in Japanese Patent Application Laid-Open No. 2004-47937, in order to supply a voltage to the N-type high-potential region provided with the high-voltage side driving circuit (high-voltage floating circuit), a high-voltage retaining part is provided so as not to apply a high voltage to a cathode of a bootstrap diode during supply of a high voltage to the high-voltage side driving circuit. An anode of the bootstrap diode is connected to a low-voltage side driving circuit.

In the conventional semiconductor device represented by the semiconductor device disclosed in Japanese Patent Application Laid-Open No. 2004-47937, a p⁺-layer surrounding an n⁺-layer in a high-voltage element part connected to the cathode of the diode is fixed to the same potential as a p⁻-substrate, thereby extending a depletion layer and relaxing an electric field.

The conventional semiconductor device having such a configuration has a problem of failing to control a cathode voltage applied to the cathode of the diode to a proper voltage not excessively high due to failure of adjusting the extension of the depletion layer.

The conventional semiconductor device having the foregoing problem fails to respond to unevenness of product performance due to fluctuations in manufacturing processes, thereby imposing limitation on layout design.

### SUMMARY

The present disclosure has been made to solve the foregoing problem, and is intended to provide a semiconductor device allowing a cathode voltage of a diode to be adjusted to a proper voltage even if a comparatively high voltage is applied to an N-type high-potential region.

A semiconductor device of the present disclosure includes a P-type semiconductor layer, an N-type high-potential region, an N-type high-breakdown voltage isolation region, a diode region, a first N-type semiconductor region and a second N-type semiconductor region, and a P-type semiconductor region.

The N-type high-potential region is provided on the P-type semiconductor layer.

The N-type high-breakdown voltage isolation region is provided on the P-type semiconductor layer in such a manner as to surround the N-type high-potential region in a plan view.

The diode region is provided on the P-type semiconductor layer independently of the N-type high-breakdown voltage isolation region, and includes a diode with an anode to be supplied with a second voltage higher than a first voltage.

The first and second N-type semiconductor regions are provided selectively in an upper layer part of the N-type high-breakdown voltage isolation region.

The P-type semiconductor region is provided selectively in the upper layer part of the N-type high-breakdown voltage isolation region and to be supplied with the first voltage lower than the second voltage.

An N-type impurity concentration in each of the first and second N-type semiconductor regions is set higher than an N-type impurity concentration in the N-type high-breakdown voltage isolation region, and the first and second N-type semiconductor regions and the P-type semiconductor region are provided in the absence of contact relationship therebetween.

The second N-type semiconductor region is arranged closer to the N-type high-potential region than the first N-type semiconductor region and the P-type semiconductor region.

The P-type semiconductor region is arranged between the first N-type semiconductor region and the N-type high-potential region in a plan view.

The diode has a cathode electrically connected to the first N-type semiconductor region.

The second N-type semiconductor region is electrically connected to the N-type high-potential region.

In the semiconductor device of the present disclosure, the first voltage to be applied to the P-type semiconductor region is set lower than the second voltage to be applied to the first N-type semiconductor region. This allows application of a reverse bias between the P-type semiconductor region and the N-type high-breakdown voltage isolation region.

Thus, using a depletion layer generated at an interface between a P-type parallel region of the P-type semiconductor region and the N-type high-breakdown voltage isolation region, it is possible to relax an electric field in a periphery of the first N-type semiconductor region electrically connected to the cathode of the diode.

As a result, even if a high-potential side power supply voltage higher than the second voltage is applied to a first electrode for the high-potential side power supply voltage, it is still possible to adjust the value of the first voltage in such a manner that a cathode voltage to be applied to the cathode of the diode becomes a proper voltage not excessively high.

Furthermore, even if a condition for the cathode voltage to become a proper voltage differs between devices due to unevenness of product performance, it is still possible to suppress the unevenness of product performance to encourage improvement in a fraction defective of devices as the semiconductor device of the present disclosure allows the value of the first voltage to be adjusted on the basis of each device.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is an explanatory view schematically showing a planar configuration of a semiconductor device according to a first preferred embodiment of the present disclosure;

FIG. 2 is an explanatory view schematically showing a planar configuration of a semiconductor device according to a second preferred embodiment of the present disclosure;

FIG. 3 is an explanatory view schematically showing a planar configuration of a semiconductor device according to a third preferred embodiment of the present disclosure;

FIG. 4 is an explanatory view schematically showing a planar configuration of a semiconductor device according to a fourth preferred embodiment of the present disclosure;

FIG. 5 is an explanatory view schematically showing a planar configuration of a semiconductor device according to a first aspect of a fifth preferred embodiment of the present disclosure;

FIG. 6 is an explanatory view schematically showing a planar configuration of a semiconductor device according to a second aspect of the fifth preferred embodiment of the present disclosure;

FIG. 7 is an explanatory view schematically showing a planar configuration of a semiconductor device according to a first aspect of a sixth preferred embodiment of the present disclosure;

FIG. 8 is an explanatory view schematically showing a planar configuration of a semiconductor device according to a second aspect of the sixth preferred embodiment of the present disclosure;

FIG. 9 is an explanatory view schematically showing a planar configuration of a semiconductor device according to a third aspect of the sixth preferred embodiment of the present disclosure;

FIG. 10 is an explanatory view schematically showing a planar configuration of a semiconductor device according to a first aspect of a seventh preferred embodiment of the present disclosure;

FIG. 11 is an explanatory view schematically showing a planar configuration of a semiconductor device according to a second aspect of the seventh preferred embodiment of the present disclosure;

FIG. 12 is an explanatory view schematically showing a planar configuration of a semiconductor device according to a third aspect of the seventh preferred embodiment of the present disclosure; and

FIG. 13 is a sectional view showing a basic configuration of a semiconductor device with an N-type high-potential region provided with a high-voltage side driving circuit.

### DESCRIPTION OF THE PREFERRED EMBODIMENTS

### <Basic Technology>

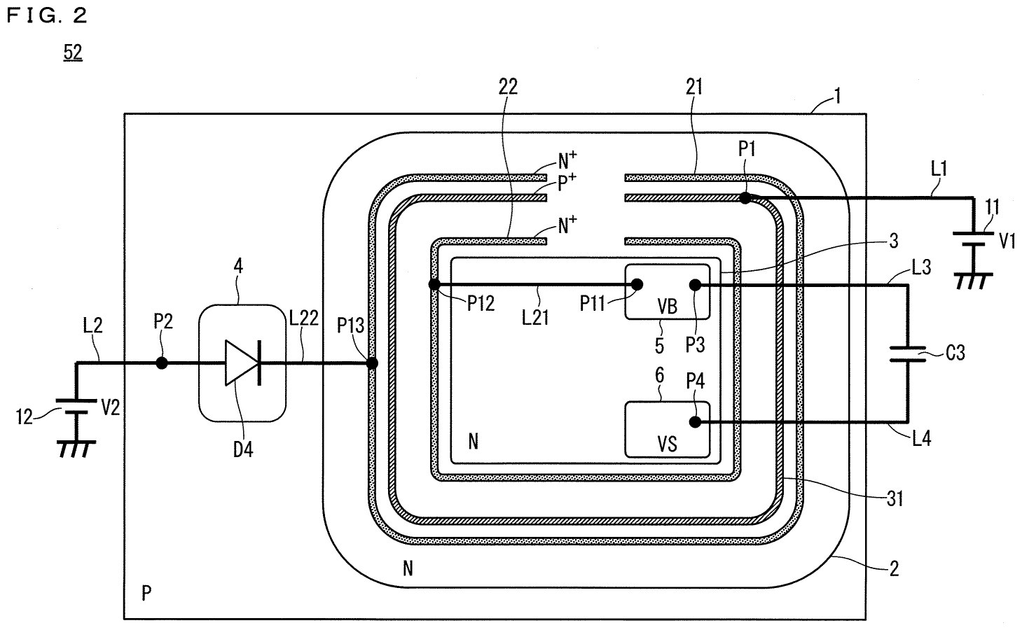

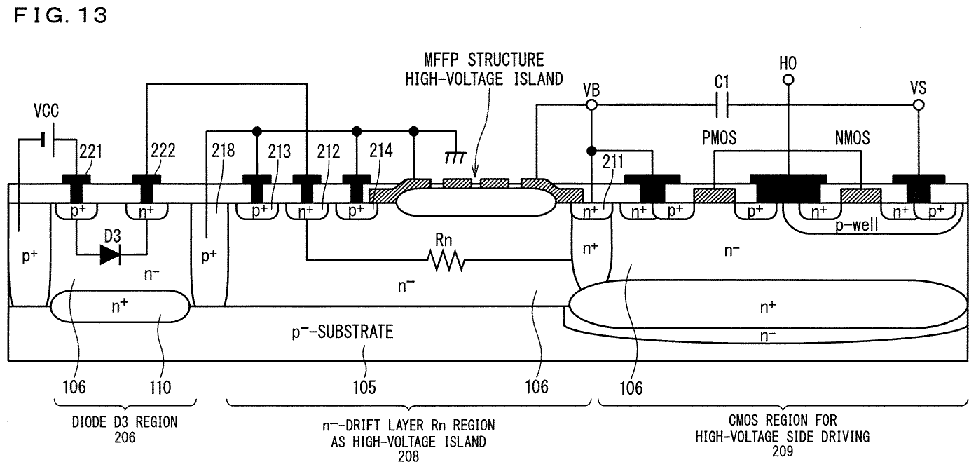

FIG. 13 is a sectional view showing a basic configuration of a semiconductor device with an N-type high-potential region provided with a high-voltage side driving circuit. FIG. 13 corresponds to FIG. 2, etc. disclosed in Japanese Patent Application Laid-Open No. 2004-47937.

FIG. 13 shows a bootstrap system where a diode D3 region 206 and an n⁻-drift layer Rn region 208 employing a high-voltage island are mounted on a monolithic high-breakdown voltage IC chip. The n⁻-drift layer Rn region 208 functions as a high-voltage retaining part.

An external capacitor C1 connected between a VB terminal and a VS terminal has one end connected through the n⁻-drift layer Rn and the diode D3 region 206 on the monolithic IC chip to Vcc at a power supply voltage of 15 V, for example.

In this way, in the monolithic high-breakdown voltage IC shown in FIG. 13, an anode p⁺-layer 221 in the diode D3 region 206 is connected to the power supply voltage Vcc. A current is caused to flow from a cathode n⁺-layer 222 into the external capacitor C1 through the n⁻-drift layer Rn to charge the external capacitor C1. The monolithic high-breakdown voltage IC shown in FIG. 13 provides a system not requiring an additional high-voltage side floating power supply by using a charging voltage supplied to the external capacitor C1 as a power supply voltage for the high-voltage side driving circuit.

The sectional configuration of the bootstrap circuit shown in FIG. 13 includes the diode D3 region 206, the n⁻-drift layer region 208 as the high-voltage island, and a CMOS transistor region 209 for high-voltage side driving. In the diode D3 region 206, a buried n⁺-layer 110 is interposed between an n⁻-semiconductor layer 106 and a p⁻-substrate 105.

The CMOS transistor region 209 for high-voltage side driving is provided with a high-voltage floating circuit functioning as the high-voltage side driving circuit.

In the n⁻-drift layer region 208 as the high-voltage island, p⁺-layers 213 and 214 at the same potential as the p⁻-substrate 105 are provided to extend a depletion layer and relax an electric field concentration in an n⁺-region 212. A p⁺-diffusion region 218 for junction isolation between the diode D3 region 206 and the n⁻-drift layer region 208 as the high-voltage island is provided as an interlayer insulating film in the n⁻-semiconductor layer 106 to a depth reaching the p⁻-substrate 105.

As clearly seen from the sectional configuration of the bootstrap circuit determined in this way, the diode D3 region 206 includes the anode p⁺-layer 221 and the cathode n⁺-layer 222 provided in the n⁻-semiconductor layer 106 in the diode D3 region 206, and the buried n⁺-layer 110 is interposed between the n⁻-semiconductor layer 106 and the p⁻-substrate 105 in the diode D3 region 206. By doing so, a base concentration is increased to reduce an HFE in a parasitic PNP transistor, thereby suppressing ON-operation of the parasitic PNP transistor. This prevents flow of a current in a direction from the anode p⁺-layer 221 toward the p⁻-substrate 105 through the n⁻-semiconductor layer 106 in the diode D3 region 206.

Meanwhile, the n⁻-drift layer region 208 as the high-voltage island employs a multiple floating field plate (MFFP). Specifically, the n⁻-drift layer Rn region 208 as the high-voltage island is surrounded by an n⁺-layer 211 on a high-potential side in the n⁻-semiconductor layer 106 in the high-voltage island, and by a pair of the p⁺-layers 213 and 214 provided on both sides of the n⁺-layer 212 in an opening part and fixed to the same potential (ground potential GND) as the p⁻-substrate 105, thereby extending a depletion layer and relaxing an electric field concentration in the n⁺-layer 212 in the opening part. Thus, while the n⁺-layer 212 in the opening part is brought to a floating potential when a power element on a high-voltage side is turned on and a power element on a low-voltage side is turned off, this potential can be controlled to a low potential to allow retention of a high voltage.

As described above, the bootstrap system relating to the semiconductor device as a basic technology shown in FIG. 13 employs the configuration where the diode D3 region 206 and the n⁻-drift layer region 208 as the high-voltage island are mounted on the high-breakdown voltage IC chip, making it possible to reduce a circuit consumption current effectively. Furthermore, the configuration of FIG. 13 providing junction isolation between the diode D3 region 206 and the n⁻-drift layer Rn region 208 as the high-voltage island allows mounting on the monolithic high-breakdown voltage IC chip.

As described above, in the conventional semiconductor device represented by the basic technology shown in FIG. 13, a pair of the p⁺-layers 213 and 214 is fixed to the same potential (ground potential GND) as the p⁻-substrate 105. This makes it impossible to adjust extension of a depletion layer in the conventional semiconductor device, causing a problem of failing to adjust a cathode voltage applied to a cathode of the diode D3 to a proper voltage not excessively high. This problem is intended to be solved by first to seventh embodiments of the present disclosure described next.

### First Preferred Embodiment

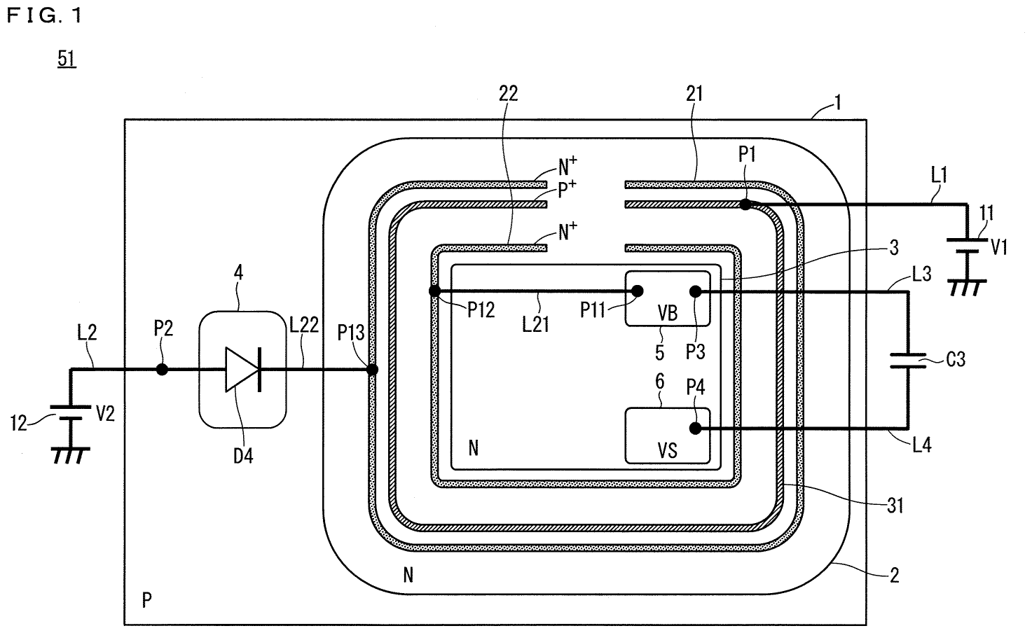

FIG. 1 is an explanatory view schematically showing a planar configuration of a semiconductor device 51 according to a first preferred embodiment of the present disclosure.

As shown in FIG. 1, the semiconductor device 51 of the first preferred embodiment includes a P-type semiconductor layer 1, an N-type high-breakdown voltage isolation region 2, an N-type high-potential region 3, and a diode region 4 provided on the P-type semiconductor layer 1, power supplies 11 and 12, and a capacitor C3 that function as principal components of the semiconductor device 51.

The P-type semiconductor layer 1, the N-type high-breakdown voltage isolation region 2, the N-type high-potential region 3, and the diode region 4 shown in FIG. 1 correspond to the p⁻-substrate 105, the n⁻-drift layer region 208 as the high-voltage island (the n⁻-semiconductor layer 106 therein), the CMOS transistor region 209 for high-voltage side driving (the n⁻-semiconductor layer 106 therein), and the diode D3 region 206 respectively, for example.

The N-type high-breakdown voltage isolation region 2 is provided on the P-type semiconductor layer 1 in such a manner as to surround the N-type high-potential region 3 completely in a plan view. Specifically, the N-type high-breakdown voltage isolation region 2 achieves a RESURF structure, for example, by surrounding the N-type high-potential region 3 in a plan view.

The diode region 4 is provided on the P-type semiconductor layer 1 independently of the N-type high-breakdown voltage isolation region 2 and the N-type high-potential region 3, and includes a diode D4 therein. The diode D4 is a bootstrap diode, and an anode of the diode D4 is connected to a low-voltage side driving circuit now shown in FIG. 1.

The N-type high-potential region 3 has a surface provided with a power supply electrode 5 as a first electrode for a high-potential side power supply voltage VB, and a reference electrode 6 as a second electrode for a high-potential region reference voltage VS.

The N-type high-breakdown voltage isolation region 2 has an upper layer part where an N-type semiconductor region 21 and an N-type semiconductor region 22 are provided selectively as a first N-type semiconductor region and a second N-type semiconductor region respectively.

A P-type semiconductor region 31 is provided selectively in the upper layer part of the N-type high-breakdown voltage isolation region 2. The N-type semiconductor regions 21 and 22 and the P-type semiconductor region 31 are provided in the upper layer part of the N-type high-breakdown voltage isolation region 2 in the absence of contact relationship therebetween.

The N-type semiconductor regions 21 and 22 shown in FIG. 1 have sectional configurations corresponding to those of the n⁺-region 212 and the n⁺-layer 211 shown in FIG. 13, for example. The P-type semiconductor region 31 shown in FIG. 1 has a sectional configuration corresponding to that of the p⁺-layer 214 shown in FIG. 13, for example.

An N-type impurity concentration in each of the N-type semiconductor regions 21 and 22 is set higher than an N-type impurity concentration in the N-type high-breakdown voltage isolation region 2. A P-type impurity concentration in the P-type semiconductor region 31 is set higher than a P-type impurity concentration in the P-type semiconductor layer 1.

The N-type high-potential region 3 has a quadrangular shape, which is a polygonal shape having three or more corners in a plan view. The N-type high-potential region 3 shown in FIG. 1 has a horizontally-long rectangular shape in a plan view. The N-type semiconductor region 22 is arranged closer to the N-type high-potential region 3 than the N-type semiconductor region 21 and the P-type semiconductor region 31. Specifically, the N-type semiconductor region 22 is arranged inside the N-type semiconductor region 21 in a plan view.

The N-type semiconductor region 21 includes a first N-type parallel region parallel to at least one side of the N-type high-potential region 3 in a plan view. The at least one side corresponds to any one of a right side, a left side, and a lower side of the N-type high-potential region 3 shown in FIG. 1.

The N-type semiconductor region 22 is arranged between the N-type high-potential region 3 and the N-type semiconductor region 21 in a plan view. The N-type semiconductor region 22 includes a second N-type parallel region parallel to the at least one side of the N-type high-potential region 3 in a plan view. The at least one side is common to the N-type semiconductor regions 21 and 22.

The P-type semiconductor region 31 includes a P-type parallel region parallel to the at least one side of the N-type high-potential region 3 in a plan view. The at least one side is common to the N-type semiconductor regions 21 and 22 and the P-type semiconductor region 31.

An entire area of the P-type semiconductor region 31 is arranged between the N-type semiconductor region 21 as the first N-type semiconductor region and the N-type semiconductor region 22 as the second N-type semiconductor region in a plan view. Thus, the P-type parallel region of the P-type semiconductor region 31 is arranged between the first N-type parallel region of the N-type semiconductor region 21 and the second N-type parallel region of the N-type semiconductor region 22 in a plan view. The P-type semiconductor region 31 is arranged between the N-type semiconductor region 21 and the N-type high-potential region 3 in a plan view.

In FIG. 1, the first N-type parallel region, the second N-type parallel region, and the P-type parallel region are regions that are apparently parallel to the three sides (right side, left side, upper side) of the N-type high-potential region 3. In the present specification, the first preferred embodiment is characterized in that “the first N-type parallel region of the N-type semiconductor region 21, the second N-type parallel region of the N-type semiconductor region 22, and the P-type parallel region of the P-type semiconductor region 31 are all parallel to the at least one side of the N-type high-potential region 3.”

In a clearance region in the N-type high-breakdown voltage isolation region 2 in the absence of the N-type semiconductor regions 21 and 22 and the P-type semiconductor region 31, a transmission element is provided for transmission of a signal between the low-voltage side driving circuit and the high-voltage side driving circuit (high-voltage floating circuit), for example. The high-voltage side driving circuit is provided in the N-type high-potential region 3.

The power supply 11 as a first power supply supplies a power supply voltage V1 as a first voltage. The power supply 12 as a second power supply supplies a power supply voltage V2 as a second voltage. The power supply voltage V1 is set lower than the power supply voltage V2. To be precise, defining that a drop voltage of the diode D4 as VF, the power supply voltage V1 is set in such a manner as to satisfy the following: {V1<(V2−VF)}.

The power supply voltage V1 from the power supply 11 is applied to the P-type semiconductor region 31 through an interconnect line L1. Specifically, one end of the interconnect line L1 is electrically connected to a node P1 on the P-type semiconductor region 31, and the other end of the interconnect line L1 is electrically connected to a positive pole of the power supply 11. A negative pole of the power supply 11 is electrically connected to a ground level as a reference potential. The power supply voltage V1 from the power supply 11 is not supplied to the P-type semiconductor layer 1.

The power supply voltage V2 from the power supply 12 is applied to the anode of the diode D4 through an interconnect line L2. Specifically, a node P2 on the interconnect line L2 and the anode of the diode D4 are electrically connected to each other, and a positive pole of the power supply 12 is electrically connected to the interconnect line L2. A negative pole of the power supply 12 is electrically connected to a ground level as a reference potential.

A cathode of the diode D4 is electrically connected to the N-type semiconductor region 21 through an interconnect line L22. Specifically, the cathode of the diode D4 is electrically connected to one end of the interconnect line L22, and a node P13 on the N-type semiconductor region 21 is electrically connected to the other end of the interconnect line L22.

Thus, the cathode of the diode D4 is electrically connected to the N-type high-potential region 3 through a high-breakdown voltage isolation element. The “high-breakdown voltage isolation element” means a region in the N-type high-breakdown voltage isolation region 2 forming electrical connection between the N-type semiconductor regions 21 and 22. The “high-breakdown voltage isolation element” corresponds to the n⁻-drift layer Rn according to the basic technology shown in FIG. 13, for example.

The N-type semiconductor region 22 is electrically connected to the power supply electrode 5 as the first electrode through an interconnect line L21. Specifically, a node P12 on the N-type semiconductor region 22 is electrically connected to one end of the interconnect line L21, and a node P11 on the power supply electrode 5 is electrically connected to the other end of the interconnect line L21. In this way, the N-type semiconductor region 22 is electrically connected to the N-type high-potential region 3.

The capacitor C3 as an external charging element has one electrode electrically connected to the power supply electrode 5 as the first electrode in the N-type high-potential region 3 through an interconnect line L3, and the other electrode connected to the reference electrode 6 as the second electrode in the N-type high-potential region 3 through a line L4.

Specifically, one end of the interconnect line L3 is electrically connected to a node P3 on the power supply electrode 5, and the other end of the interconnect line L3 is electrically connected to the one electrode of the capacitor C3. One end of the interconnect line L4 is electrically connected to a node P4 on the reference electrode 6, and the other end of the interconnect line L4 is electrically connected to the other electrode of the capacitor C3.

The capacitor C3 and the diode D4 can be used for forming a bootstrap circuit. Thus, electrical charge supplied to the capacitor C3 can be used for driving a high-potential side driving circuit provided in the N-type high-potential region 3.

The electrical connection between the power supplies 11 and 12 and the capacitor C3 is formed by a method not limited to the above-described method using the interconnect lines L1 to L4 and L22 but may be formed by a different method. For example, a pattern interconnect line may be provided on the P-type semiconductor layer 1. Alternatively, electrical connection to a power supply provided externally (corresponding to the power supplies 11 and 12) or to the capacitor C3 may be formed using a wire interconnect line through an electrode pad provided on the power supply electrode 5 or the reference electrode 6.

In the semiconductor device 51 of the first preferred embodiment, the power supply voltage V1 as the first voltage to be applied to the P-type semiconductor region 31 is set lower than the power supply voltage V2 as the second voltage to be applied to the N-type semiconductor region 21. This allows application of a reverse bias between the P-type semiconductor region 31 and the N-type high-breakdown voltage isolation region 2.

Thus, using a depletion layer generated at an interface between the P-type parallel region of the P-type semiconductor region 31 and the N-type high-breakdown voltage isolation region 2, it is possible to relax an electric field in a periphery of the N-type semiconductor region 21 electrically connected to the cathode of the diode D4.

As a result, even if the high-potential side power supply voltage VB higher than the power supply voltage V2 is applied to the power supply electrode 5, it is still possible to adjust the value of the power supply voltage V1 as the first voltage in such a manner that a cathode voltage to be applied to the cathode of the diode D4 forming the bootstrap circuit becomes a proper voltage not excessively high.

A reason for this is that the power supply voltage V1 supplied from the power supply 11 is used as a set voltage exclusively for the P-type semiconductor region 31. Specifically, unlike a set potential of the pair of p⁺-layers 213 and 214 according to the basic technology shown in FIG. 13, the power supply voltage V1 is free from the limitation of being fixed to the same potential as the p⁻-substrate 105.

Thus, in the semiconductor device 51 of the first preferred embodiment, the power supply voltage V1 can be changed without being subjected to the above-described limitation. This makes it possible to adjust extension of the above-described depletion layer with high accuracy in such a manner that a cathode voltage of the diode D4 becomes a proper voltage. This further makes it possible to improve a degree of freedom in designing a layout of the semiconductor device 51.

Even if a condition for a cathode voltage of the diode D4 to become a proper voltage differs between devices due to unevenness of product performance, it is still possible to suppress the unevenness of product performance to encourage improvement in a fraction defective of devices as the semiconductor device 51 of the first preferred embodiment allows the value of the power supply voltage V1 to be adjusted individually on the basis of each device.

In the semiconductor device 51 of the first preferred embodiment, the bootstrap circuit is configured using the diode D4 and the capacitor C3 as a charging element. This allows the high-potential side driving circuit provided in the N-type high-potential region 3 to be driven by discharging a charging voltage supplied to the capacitor C3.

### Second Preferred Embodiment

FIG. 2 is an explanatory view schematically showing a planar configuration of a semiconductor device 52 according to a second preferred embodiment of the present disclosure.

As shown in FIG. 2, like that of the first preferred embodiment, the semiconductor device 52 of the second preferred embodiment includes a P-type semiconductor layer 1, an N-type high-breakdown voltage isolation region 2, an N-type high-potential region 3, and a diode region 4 provided on the P-type semiconductor layer 1, power supplies 11 and 12, and a capacitor C3 that function as principal components of the semiconductor device 52.

The semiconductor device 52 of the second preferred embodiment has all the characteristics of the semiconductor device 51 of the first preferred embodiment shown in FIG. 1, and additionally has the following characteristics.

The N-type semiconductor region 21 includes a first N-type parallel region parallel to three sides of the N-type high-potential region 3 in a plan view. The three sides correspond to the right side, the left side, and the lower side of the N-type high-potential region 3 shown in FIG. 2. The first N-type parallel region further includes a region parallel to a part of the upper side of the N-type high-potential region 3.

As described above, the N-type semiconductor region 21 includes the first N-type parallel region parallel to the at least three sides of the N-type high-potential region 3 in a plan view. Thus, the N-type semiconductor region 21 surrounds the N-type high-potential region 3 over a region exceeding ¾ of an outer perimeter thereof in a plan view.

The N-type semiconductor region 22 includes a second N-type parallel region parallel to the three sides of the N-type high-potential region 3 in a plan view. The three sides correspond to the right side, the left side, and the lower side of the N-type high-potential region 3 shown in FIG. 2. The second N-type parallel region further includes a region parallel to a part of the upper side of the N-type high-potential region 3.

As described above, the N-type semiconductor region 22 includes the second N-type parallel region parallel to the at least three sides of the N-type high-potential region 3 in a plan view. The at least three sides are common to the N-type semiconductor regions 21 and 22. Thus, the N-type semiconductor region 22 surrounds the N-type high-potential region 3 over a region exceeding ¾ of the outer perimeter thereof in a plan view.

The P-type semiconductor region 31 includes a P-type parallel region parallel to the at least three sides of the N-type high-potential region 3 in a plan view. The three sides correspond to the right side, the left side, and the lower side of the N-type high-potential region 3 shown in FIG. 2. The P-type parallel region further includes a region parallel to a part of the upper side of the N-type high-potential region 3.

As described above, the P-type semiconductor region 31 includes the P-type parallel region parallel to the at least three sides of the N-type high-potential region 3 in a plan view. The at least three sides are common to the N-type semiconductor regions 21 and 22 and the P-type semiconductor region 31. Thus, the P-type semiconductor region 31 surrounds the N-type high-potential region 3 over a region exceeding ¾ of the outer perimeter thereof in a plan view.

Thus, as shown in FIG. 2, the semiconductor device 52 of the second preferred embodiment is characterized in that “the first N-type parallel region of the N-type semiconductor region 21, the second N-type parallel region of the N-type semiconductor region 22, and the P-type parallel region of the P-type semiconductor region 31 are all parallel to the at least three sides of the N-type high-potential region 3.”

An entire area of the P-type semiconductor region 31 is arranged between the N-type semiconductor region 21 and the N-type semiconductor region 22 in a plan view. Thus, the P-type parallel region of the P-type semiconductor region 31 is arranged between the first N-type parallel region of the N-type semiconductor region 21 and the second N-type parallel region of the N-type semiconductor region 22 in a plan view.

As a result, in the semiconductor device 52 of the second preferred embodiment, the N-type semiconductor regions 21 and 22 and the P-type semiconductor region 31 are each arranged in such a manner as to surround half or more of the outer perimeter of the N-type high-potential region 3 in a plan view. In addition, the P-type semiconductor region 31 is arranged in such a manner as to surround half or more of an outer perimeter of the N-type semiconductor region 22, and the N-type semiconductor region 21 is arranged in such a manner as to surround half or more of an outer perimeter of the P-type semiconductor region 31.

In the semiconductor device 52 of the second preferred embodiment, the power supply voltage V1 as the first voltage to be applied to the P-type semiconductor region 31 is set lower than the power supply voltage V2 as the second voltage to be applied to the N-type semiconductor region 21. This allows application of a reverse bias between the P-type semiconductor region 31 and the N-type high-breakdown voltage isolation region 2.

Thus, the semiconductor device 52 of the second preferred embodiment makes it possible to relax an electric field in a periphery of the N-type semiconductor region 21 electrically connected to the cathode of the diode D4 using a depletion layer generated at an interface between the P-type parallel region of the P-type semiconductor region 31 and the N-type high-breakdown voltage isolation region 2.

As a result, like that of the first preferred embodiment, the semiconductor device 52 of the second preferred embodiment can improve a degree of freedom in designing a layout of the semiconductor device 52, suppress unevenness of product performance, and encourage improvement in a fraction defective of devices.

In addition, in the second preferred embodiment, the P-type parallel region of the P-type semiconductor region 31, and the first and second N-type parallel regions of the N-type semiconductor regions 21 and 22 respectively are parallel to the at least three sides of the N-type high-potential region 3. The at least three sides are common to the N-type semiconductor regions 21 and 22 and the P-type semiconductor region 31.

Thus, each of the first and second N-type parallel regions and the P-type parallel region is spaced from the at least three sides of the N-type high-potential region 3 by an equal distance. Furthermore, in the semiconductor device 52 of the second preferred embodiment, applying a reverse bias between the P-type semiconductor region 31 and the N-type high-breakdown voltage isolation region 2 provides a depletion layer along the P-type parallel region of the P-type semiconductor region 31 parallel to the at least three sides of the N-type high-potential region 3.

As a result, in the semiconductor device 52 of the second preferred embodiment, it is possible to set a uniform electric field in a periphery of each of the N-type semiconductor regions 21 and 22 and the P-type semiconductor region 31. This accordingly improves accuracy in adjusting a cathode voltage of the diode D4, making it possible to improve the reliability of the device compared to the first preferred embodiment. This will be described next in more detail.

As the P-type parallel region of the P-type semiconductor region 31 is parallel to the at least three sides of the N-type high-potential region 3, the P-type parallel region of the P-type semiconductor region 31 is spaced at an equal distance from the N-type high-potential region 3. This makes an electric field uniform at any position in the P-type parallel region of the P-type semiconductor region 31 to make a depletion layer extend correspondingly toward the N-type semiconductor region 21. Thus, it becomes possible to adjust a cathode voltage of the diode D4 with high accuracy using the power supply voltage V1 applied to the P-type semiconductor region 31.

The semiconductor device 51 of the first preferred embodiment also achieves the effect of making an electric field uniform at any position in the P-type parallel region of the P-type semiconductor region 31 for the reason that the P-type parallel region is parallel to the at least one side of the N-type high-potential region 3. In addition, in order to make the above-described depletion layer extend more uniformly, it is desirable for the P-type semiconductor region 31 and the N-type semiconductor regions 21 and 22 to be formed into an equal width.

In addition, the N-type semiconductor regions 21 and 22 and the P-type semiconductor region 31 forming the semiconductor device 52 of the second preferred embodiment are each arranged in such a manner as to surround half or more of the outer perimeter of the N-type high-potential region 3 in a plan view.

Thus, using the depletion layer generated over a comparatively wide range at an interface between the P-type semiconductor region 31 and the N-type high-breakdown voltage isolation region 2, it is possible to relax an electric field in a peripheral region of the N-type semiconductor region 21. This accordingly makes it possible to enhance performance in controlling a cathode voltage of the diode D4.

Each of the N-type semiconductor regions 21 and 22 and the P-type semiconductor region 31 forming the semiconductor device 52 of the second preferred embodiment surrounds the N-type high-potential region 3 over a range exceeding ¾ of the outer perimeter thereof in a plan view. This makes it possible to enhance performance further in controlling a cathode voltage of the diode D4.

In order to block a current path between the N-type semiconductor regions 21 and 22 to sufficiently achieve the effect of controlling a cathode voltage of the diode D4, it is desirable for the P-type semiconductor region 31 to surround the N-type high-potential region 3 over a range substantially equal to a range of surrounding the N-type high-potential region 3 by each of the N-type semiconductor regions 21 and 22.

### Third Preferred Embodiment

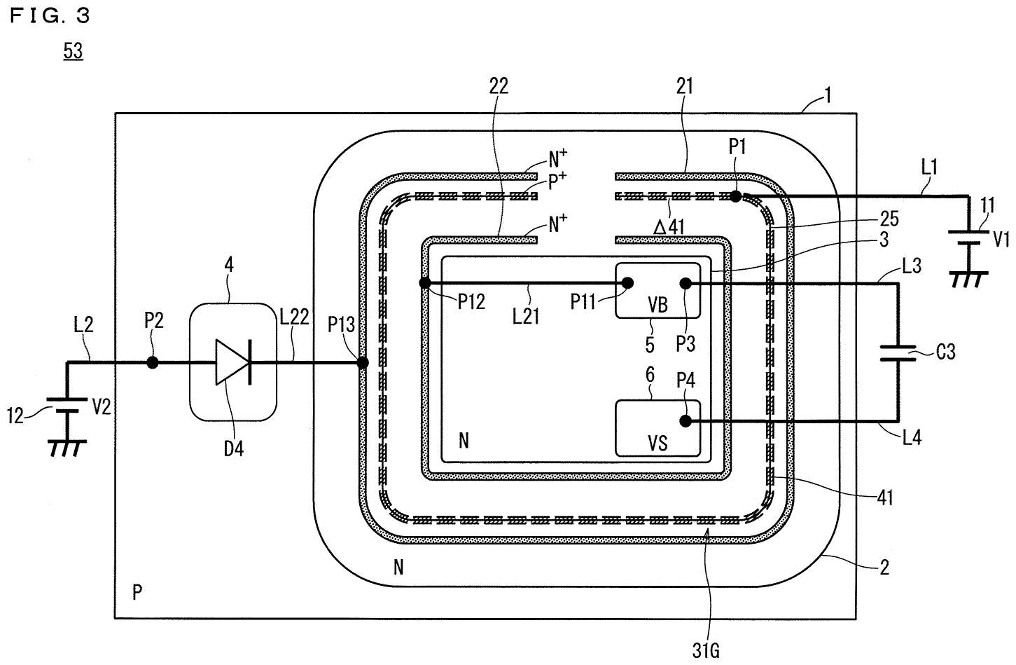

FIG. 3 is an explanatory view schematically showing a planar configuration of a semiconductor device 53 according to a third preferred embodiment of the present disclosure.

As shown in FIG. 3, like those of the first preferred embodiment and the second preferred embodiment, the semiconductor device 53 of the third preferred embodiment includes a P-type semiconductor layer 1, an N-type high-breakdown voltage isolation region 2, an N-type high-potential region 3, and a diode region 4 provided on the P-type semiconductor layer 1, power supplies 11 and 12, and a capacitor C3 that function as principal components of the semiconductor device 53.

In the following, structures similar to those of the first preferred embodiment and the second preferred embodiment shown in FIGS. 1 and 2 will be given the same signs and descriptions thereof will be omitted as appropriate, and characteristic parts of the semiconductor device 53 of the third preferred embodiment will be described mainly.

Compared to those of the first preferred embodiment and the second preferred embodiment, the semiconductor device 53 of the third preferred embodiment is characterized in that a P-type semiconductor region group 31G is provided instead of the P-type semiconductor region 31. Specifically, the P-type semiconductor region group 31G corresponds to a P-type semiconductor region in the semiconductor device 53 of the third preferred embodiment. The sectional configuration of the P-type semiconductor region group 31G shown in FIG. 3 is similar to that of the P-type semiconductor region 31 shown in each of the first preferred embodiment and the second preferred embodiment.

The P-type semiconductor region group 31G is composed of a plurality of P-type partial semiconductor regions 41 provided separately from each other. A P-type impurity concentration in each of the P-type partial semiconductor regions 41 belonging to the P-type semiconductor region group 31G is set higher than a P-type impurity concentration in the P-type semiconductor layer 1.

Like the P-type semiconductor region 31 of the second preferred embodiment, the P-type semiconductor region group 31G includes a P-type parallel region parallel to three sides of the N-type high-potential region 3 in a plan view. The three sides correspond to the right side, the left side, and the lower side of the N-type high-potential region 3 shown in FIG. 3. The P-type parallel region further includes a region parallel to a part of the upper side of the N-type high-potential region 3.

As described above, the P-type semiconductor region group 31G includes the P-type parallel region parallel to the at least three sides of the N-type high-potential region 3 in a plan view. The at least three sides are common to the N-type semiconductor regions 21 and 22 and the P-type semiconductor region group 31G. Thus, the P-type semiconductor region group 31G surrounds the N-type high-potential region 3 over a region exceeding ¾ of the outer perimeter thereof in a plan view.

A relay interconnect line 25 electrically connected to each of the P-type partial semiconductor regions 41 is provided in the P-type semiconductor region group 31G. The relay interconnect line 25 is electrically connected to the interconnect line L1 through the node P1.

Thus, the power supply voltage V1 from the power supply 11 is applied through the relay interconnect line 25 to each of the P-type partial semiconductor regions 41 forming the P-type semiconductor region group 31G.

In the semiconductor device 53 of the third preferred embodiment having the above-described configuration, the power supply voltage V1 to be applied to the P-type semiconductor region group 31G is set lower than the power supply voltage V2 to be applied to the N-type semiconductor region 21. This allows application of a reverse bias between the P-type semiconductor region group 31G and the N-type high-breakdown voltage isolation region 2.

Thus, like those of the first preferred embodiment and the second preferred embodiment, the semiconductor device 53 of the third preferred embodiment makes it possible to relax an electric field in the periphery of the N-type semiconductor region 21 using a depletion layer generated at an interface between the P-type semiconductor region group 31G and the N-type high-breakdown voltage isolation region 2.

As all the P-type partial semiconductor regions 41 of the P-type semiconductor region group 31G are arranged separately from each other, it is possible to relax an electric field in the periphery of the N-type semiconductor region 21 on the basis of each local and partial depletion layer corresponding to each of the plurality of P-type partial semiconductor regions 41.

As a result, in the semiconductor device 53 of the third preferred embodiment, it is possible to adjust a cathode voltage of the diode D4 finely by adjusting a gap Δ41 between the P-type partial semiconductor regions 41, 41 adjacent to each other of the plurality of P-type partial semiconductor regions 41. This accordingly makes it possible to encourage improvement in a degree of freedom in making design in the semiconductor device 53 in terms of a circuit, layout, and others.

If limitation is imposed on the power supply voltage V1 of the power supply 11 for reason such as layout design, for example, a cathode voltage of the diode D4 can still be adjusted by adjusting the gap Δ41 between the adjacent P-type partial semiconductor regions 41, 41. Setting the gap Δ41 comparatively large tends to increase a cathode voltage of the diode D4. Setting the gap Δ41 comparatively small tends to reduce a cathode voltage of the diode D4. Such tendency of the gap Δ41 can be used for adjusting a cathode voltage of the diode D4.

### Fourth Preferred Embodiment

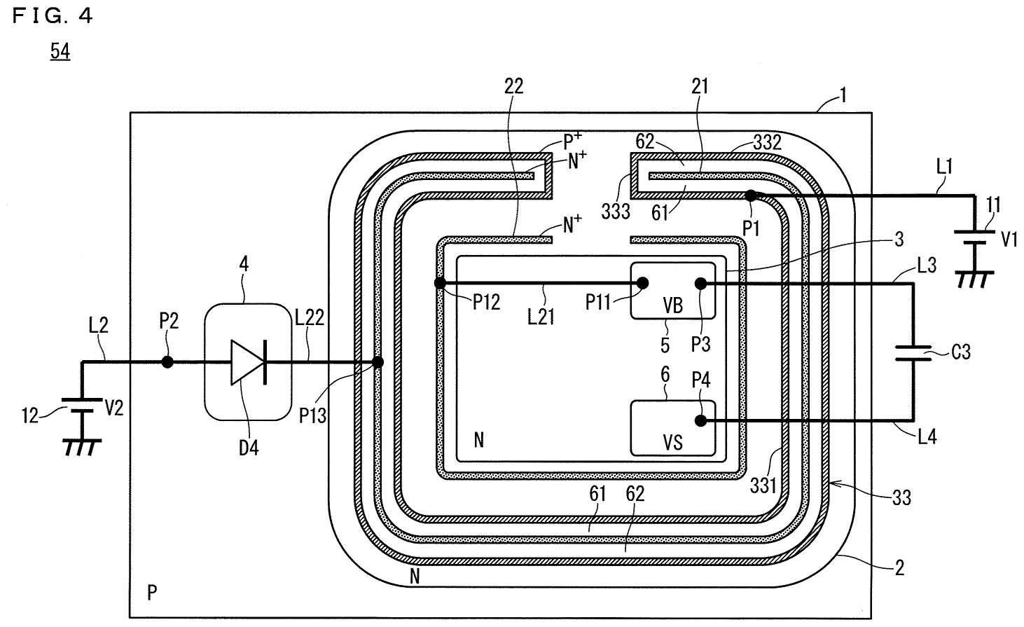

FIG. 4 is an explanatory view schematically showing a planar configuration of a semiconductor device 54 according to a fourth preferred embodiment of the present disclosure.

As shown in FIG. 4, like those of the first preferred embodiment to the third preferred embodiment, the semiconductor device 54 of the fourth preferred embodiment includes a P-type semiconductor layer 1, an N-type high-breakdown voltage isolation region 2, an N-type high-potential region 3, and a diode region 4 provided on the P-type semiconductor layer 1, power supplies 11 and 12, and a capacitor C3 that function as principal components of the semiconductor device 54.

In the following, structures similar to those of the first preferred embodiment and the second preferred embodiment shown in FIGS. 1 and 2 will be given the same signs and descriptions thereof will be omitted as appropriate, and characteristic parts of the semiconductor device 54 of the fourth preferred embodiment will be described mainly.

Compared to those of the first preferred embodiment and the second preferred embodiment, the semiconductor device 54 of the fourth preferred embodiment is characterized in that a P-type semiconductor region 33 is provided instead of the P-type semiconductor region 31. Specifically, the P-type semiconductor region 33 corresponds to a P-type semiconductor region in the semiconductor device 54 of the fourth preferred embodiment.

In the N-type high-breakdown voltage isolation region 2, a peripheral region of the N-type semiconductor region 21 as the first N-type semiconductor region includes a peripheral region 61 as a first peripheral region closer to the N-type semiconductor region 22 (on an internal side), and a peripheral region 62 as a second peripheral region farther from the N-type semiconductor region 22 (on an external side).

The P-type semiconductor region 33 is provided in such a manner as to tightly surround the periphery of the N-type semiconductor region 21 as the first N-type semiconductor region without a gap in a plan view. A P-type impurity concentration in the P-type semiconductor region 33 is set higher than a P-type impurity concentration in the P-type semiconductor layer 1.

In the present specification, a “surrounding P-type semiconductor region” means a region provided in at least a part of each of the peripheral regions 61 and 62 of the N-type semiconductor region 21 in such a manner as to surround the periphery of the N-type semiconductor region 21 in a plan view. Meanwhile, a “completely surrounding P-type semiconductor region” belonging to the “surrounding P-type semiconductor region” means a region provided in the peripheral regions 61 and 62 of the N-type semiconductor region 21 in such a manner as to surround the periphery of the N-type semiconductor region 21 without a gap in a plan view.

Thus, the P-type semiconductor region 33 is the completely surrounding P-type semiconductor region. The P-type semiconductor region 33 includes an internal P-type parallel region 331 and an external P-type parallel region 332 as P-type parallel regions, and a connection region 333. The internal P-type parallel region 331 is formed in the peripheral region 61 as the first peripheral region. The external P-type parallel region 332 is formed in the peripheral region 62 as the second peripheral region. The connection region 333 connects the internal P-type parallel region 331 and the external P-type parallel region 332 to each other.

Like the P-type semiconductor region 31 of the second preferred embodiment, the internal P-type parallel region 331 is parallel to three sides of the N-type high-potential region 3 in a plan view. The three sides correspond to the right side, the left side, and the lower side of the N-type high-potential region 3 shown in FIG. 4. The internal P-type parallel region 331 further includes a region parallel to a part of the upper side of the N-type high-potential region 3.

As described above, the internal P-type parallel region 331 is parallel to the at least three sides of the N-type high-potential region 3 in a plan view. The at least three sides are common to the N-type semiconductor regions 21 and 22 and the internal P-type parallel region 331. Thus, the internal P-type parallel region 331 surrounds the N-type high-potential region 3 over a region exceeding ¾ of the outer perimeter thereof in a plan view.

The external P-type parallel region 332 is parallel to the three sides of the N-type high-potential region 3 in a plan view. The three sides correspond to the right side, the left side, and the lower side of the N-type high-potential region 3 shown in FIG. 4. The external P-type parallel region 332 further includes a region parallel to a part of the upper side of the N-type high-potential region 3.

As described above, the external P-type parallel region 332 is parallel to the at least three sides of the N-type high-potential region 3 in a plan view. The at least three sides are common to the N-type semiconductor regions 21 and 22, the internal P-type parallel region 331, and the external P-type parallel region 332. Thus, the external P-type parallel region 332 surrounds the N-type high-potential region 3 over a region exceeding ¾ of the outer perimeter thereof in a plan view.

As described above, the P-type semiconductor region 33 as the completely surrounding P-type semiconductor region includes the internal P-type parallel region 331 and the external P-type parallel region 332 as P-type parallel regions.

Like that of the P-type semiconductor region 31 shown in each of the first preferred embodiment and the second preferred embodiment, the sectional configuration of the P-type semiconductor region 33 shown in FIG. 4 corresponds to that of the p⁺-layer 213 or the p⁺-layer 214 shown in FIG. 13, for example.

Like the P-type semiconductor region 31 of each of the first preferred embodiment and the second preferred embodiment, an entire area of the internal P-type parallel region 331 of the P-type semiconductor region 33 is arranged between the N-type semiconductor region 21 and the N-type semiconductor region 22 in a plan view. Thus, the internal P-type parallel region 331 is arranged between the first N-type parallel region of the N-type semiconductor region 21 and the second N-type parallel region of the N-type semiconductor region 22 in a plan view.

In the semiconductor device 54 of the fourth preferred embodiment having the above-described configuration, the power supply voltage V1 to be applied to the P-type semiconductor region 33 is set lower than the power supply voltage V2 to be applied to the N-type semiconductor region 21. This allows application of a reverse bias between the P-type semiconductor region 33 and the N-type high-breakdown voltage isolation region 2.

As a result, the semiconductor device 54 of the fourth preferred embodiment achieves effects comparable to those of the first preferred embodiment and the second preferred embodiment.

In addition, the P-type semiconductor region 33 as the completely surrounding P-type semiconductor region is provided in such a manner as to surround the periphery of the N-type semiconductor region 21 including the peripheral regions 61 and 62 in a plan view. Thus, the above-described depletion layer is a surrounding depletion layer surrounding the N-type semiconductor region 21.

As a result, in the semiconductor device 54 of the fourth preferred embodiment, it is possible to relax an electric field in the periphery of the N-type semiconductor region 21 including the peripheral regions 61 and 62 during application of a reverse bias.

Furthermore, as the P-type semiconductor region 33 as the completely surrounding P-type semiconductor region is provided in such a manner as to surround the periphery of the N-type semiconductor region 21 without a gap in a plan view, the N-type semiconductor region 21 is surrounded by the depletion layer from every direction. This accordingly makes it possible to enhance the effect of controlling a cathode voltage of the diode D4 when the high-potential side power supply voltage VB higher than the power supply voltage V2 is applied to the power supply electrode 5.

### Fifth Preferred Embodiment

### (First Aspect)

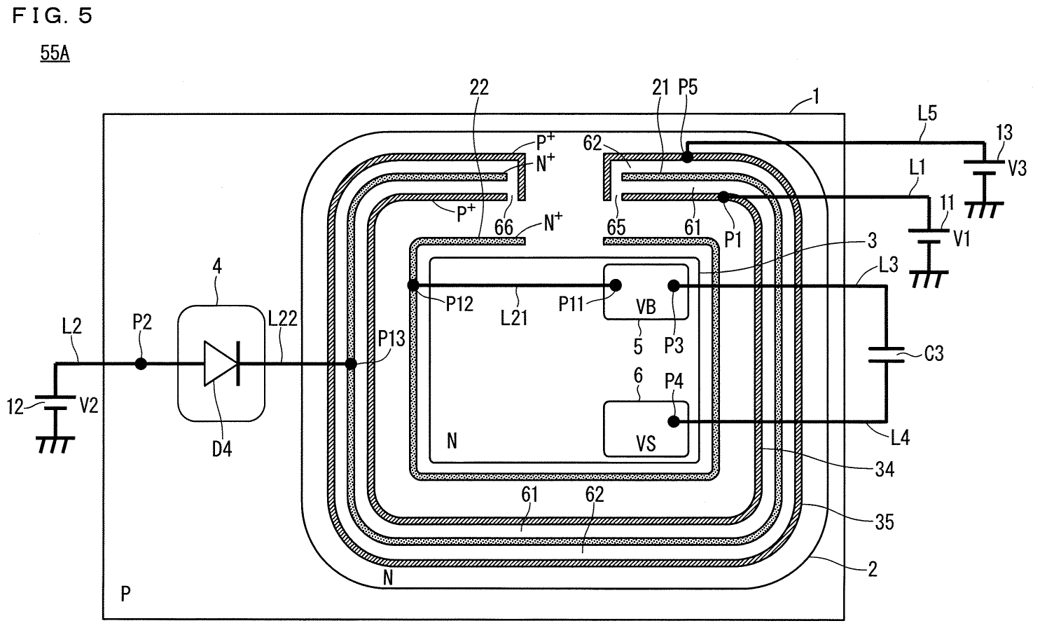

FIG. 5 is an explanatory view schematically showing a planar configuration of a semiconductor device 55A according to a first aspect of a fifth preferred embodiment of the present disclosure.

As shown in FIG. 5, the semiconductor device 55A according to the first aspect of the fifth preferred embodiment includes a P-type semiconductor layer 1, an N-type high-breakdown voltage isolation region 2, an N-type high-potential region 3, and a diode region 4 provided on the P-type semiconductor layer 1, power supplies 11 to 13, and a capacitor C3 that function as principal components of the semiconductor device 55A.

In the following, structures similar to those of the fourth preferred embodiment shown in FIG. 4 will be given the same signs and descriptions thereof will be omitted as appropriate, and characteristic parts of the semiconductor device 55A according to the first aspect of the fifth preferred embodiment will be described mainly.

Compared to that of the fourth preferred embodiment, the semiconductor device 55A of the fifth preferred embodiment is characterized in that P-type semiconductor regions 34 and 35 in a pair are provided instead of the P-type semiconductor region 33. Specifically, the P-type semiconductor regions 34 and 35 in a pair correspond to a P-type semiconductor region and a surrounding P-type semiconductor region in the semiconductor device 55A according to the first aspect of the fifth preferred embodiment.

Like in the semiconductor device 54 of the fourth preferred embodiment, in the N-type high-breakdown voltage isolation region 2, a peripheral region of the N-type semiconductor region 21 includes the peripheral region 61 as the first peripheral region closer to the N-type semiconductor region 22, and the peripheral region 62 as the second peripheral region farther from the N-type semiconductor region 22.

The P-type semiconductor region 34 and the P-type semiconductor region 35 are provided independently of each other in the absence of contact relationship therebetween. A P-type impurity concentration in each of the P-type semiconductor regions 34 and 35 in a pair is set higher than a P-type impurity concentration in the P-type semiconductor layer 1.

A combination of the P-type semiconductor regions 34 and 35 in a pair forming the surrounding P-type semiconductor region is provided in such a manner as to surround the periphery of the N-type semiconductor region 21 as the first N-type semiconductor region in a plan view.

The P-type semiconductor region 34 functions as a first partially surrounding P-type semiconductor region provided in at least a part of the peripheral region 61 of the N-type semiconductor region 21. The P-type semiconductor region 35 functions as a second partially surrounding P-type semiconductor region provided in at least a part of the peripheral region 62 of the N-type semiconductor region 21.

The P-type semiconductor region 34 provided in the peripheral region 61 corresponds to the internal P-type parallel region 331 of the P-type semiconductor region 33 shown in FIG. 4. Likewise, the P-type semiconductor region 35 provided in the peripheral region 62 corresponds to the external P-type parallel region 332 and the connection region 333 of the P-type semiconductor region 33 shown in FIG. 4.

Thus, the surrounding P-type semiconductor region composed of the combination of the P-type semiconductor regions 34 and 35 in a pair has a planar configuration and a sectional configuration similar to those of the P-type semiconductor region 33 of the fourth preferred embodiment including the internal P-type parallel region 331, the external P-type parallel region 332, and the connection region 333.

Specifically, like the internal P-type parallel region 331 of the P-type semiconductor region 33, the P-type semiconductor region 34 includes a first partial parallel region that is a region parallel to at least three sides of the N-type high-potential region 3 in a plan view. Like the external P-type parallel region 332 of the P-type semiconductor region 33, the P-type semiconductor region 35 includes a second partial parallel region that is a region parallel to the at least three sides of the N-type high-potential region 3 in a plan view. In this way, the P-type semiconductor regions 34 and 35 in a pair include the first and second partial parallel regions as P-type parallel regions.

The P-type semiconductor region 34 as the first partially surrounding P-type semiconductor region and the P-type semiconductor region 35 as the second partially surrounding P-type semiconductor region are provided separately from each other. Thus, clearance regions 65 and 66 are present between the P-type semiconductor region 34 and the P-type semiconductor region 35.

As described above, the P-type semiconductor regions 34 and 35 in a pair are provided in such a manner as to surround the periphery of the N-type semiconductor region 21 while the clearance regions 65 and 66 are opened in a plan view. It is desirable that the clearance regions 65 and 66 between the P-type semiconductor region 34 and the P-type semiconductor region 35 be narrower in terms of controlling increase in a cathode voltage of the diode D4.

An entire area of the P-type semiconductor region 34 corresponding to the internal P-type parallel region 331 of the P-type semiconductor region 33 is arranged between the N-type semiconductor region 21 and the N-type semiconductor region 22 in a plan view. Thus, like the internal P-type parallel region 331 of the P-type semiconductor region 33, the first partial parallel region belonging to the P-type semiconductor region 34 is arranged between the first N-type parallel region of the N-type semiconductor region 21 and the second N-type parallel region of the N-type semiconductor region 22 in a plan view.

The semiconductor device 55A according to the first aspect of the fifth preferred embodiment further includes the power supply 13 as a third power supply to supply a power supply voltage V3 as a third voltage. The power supply voltage V3 as the third voltage is set lower than the power supply voltage V2 as the second voltage. To be precise, defining that a drop voltage of the diode D4 as VF, the power supply voltage V3 is set in such a manner as to satisfy the following: {V3<(V2−VF)}.

A magnitude relationship between the power supply voltage V1 and the power supply voltage V3 is determined arbitrarily. Specifically, a magnitude relationship between the power supply voltage V1 and the power supply voltage V3 is arbitrarily settable within a range in which {V1<V2, V3<V2} is satisfied.

The power supply voltage V1 is applied from the power supply 11 to the P-type semiconductor region 34 as the first partially surrounding P-type semiconductor region through the interconnect line L1. Specifically, the node P1 on the P-type semiconductor region 34 is electrically connected to one end of the interconnect line L1.

The power supply voltage V3 as the third voltage is applied to the P-type semiconductor region 35 as the second partially surrounding P-type semiconductor region through an interconnect line L5. Specifically, a node P5 on the P-type semiconductor region 35 is electrically connected to one end of the interconnect line L5, and a positive pole of the power supply 13 is connected to the other end of the interconnect line L5. A negative pole of the power supply 13 is electrically connected to a ground level as a reference potential. The power supply voltage V3 from the power supply 13 is not supplied to the P-type semiconductor layer 1.

In the semiconductor device 55A of the first aspect of the fifth preferred embodiment having the above-described configuration, the power supply voltage V1 to be applied to the P-type semiconductor region 34 and the power supply voltage V3 to be applied to the P-type semiconductor region 35 are set lower than the power supply voltage V2 to be applied to the N-type semiconductor region 21. This allows application of a reverse bias between each of the P-type semiconductor regions 34 and 35 in a pair and the N-type high-breakdown voltage isolation region 2.

As a result, the semiconductor device 55A of the first aspect of the fifth preferred embodiment achieves effects comparable to those of the first preferred embodiment and the second preferred embodiment.

In addition, the P-type semiconductor regions 34 and 35 in a pair forming the surrounding P-type semiconductor region are provided in such a manner as to surround the periphery of the N-type semiconductor region 21 including the peripheral regions 61 and 62 in a plan view. Thus, the above-described depletion layer is a surrounding depletion layer surrounding the N-type semiconductor region 21.

Specifically, a first peripheral depletion layer is provided at an interface between the P-type semiconductor region 34 as a first surrounding P-type semiconductor region and the N-type high-breakdown voltage isolation region 2. A second peripheral depletion layer is provided at an interface between the P-type semiconductor region 35 as a second surrounding P-type semiconductor region and the N-type high-breakdown voltage isolation region 2. A combination of the first and second peripheral depletion layers is a surrounding depletion layer.

As a result, in the semiconductor device 55A of the first aspect of the fifth preferred embodiment, it is possible to surround the N-type semiconductor region 21 using the first and second peripheral depletion layers in a plan view. This allows relaxation of an electric field in the periphery of the N-type semiconductor region 21.

In addition, as the power supply voltage V1 and the power supply voltage V3 are individually settable, it is possible to make a difference between extension of the first peripheral depletion layer and extension of the second peripheral depletion layer toward the N-type semiconductor region 21. Thus, the semiconductor device 55A of the first aspect of the fifth preferred embodiment achieves the unique effect of allowing an electric field distribution in the periphery of the N-type semiconductor region 21 to be adjusted comparatively easily.

### (Second Aspect)

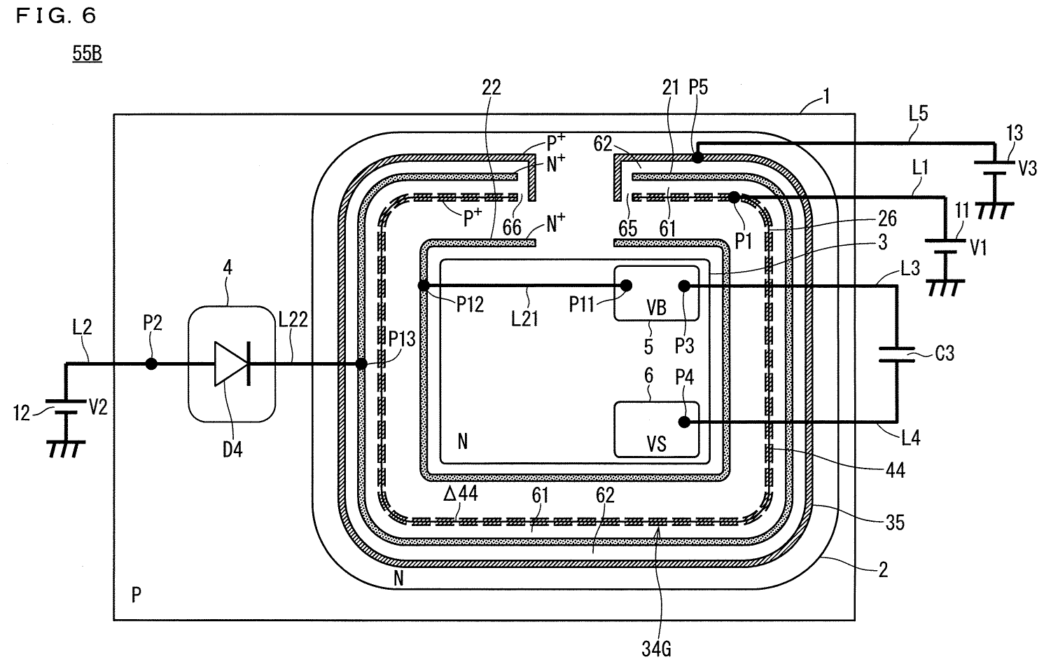

FIG. 6 is an explanatory view schematically showing a planar configuration of a semiconductor device 55B according to a second aspect of the fifth preferred embodiment of the present disclosure.

As shown in FIG. 6, like that of the first aspect of the fifth preferred embodiment shown in FIG. 5, the semiconductor device 55B according to the second aspect of the fifth preferred embodiment includes a P-type semiconductor layer 1, an N-type high-breakdown voltage isolation region 2, an N-type high-potential region 3, and a diode region 4 provided on the P-type semiconductor layer 1, power supplies 11 to 13, and a capacitor C3 that function as principal components of the semiconductor device 55B.

In the following, structures similar to those of the first aspect of the fifth preferred embodiment shown in FIG. 5 will be given the same signs and descriptions thereof will be omitted as appropriate, and characteristic parts of the semiconductor device 55B according to the second aspect of the fifth preferred embodiment will be described mainly.

Compared to the semiconductor device 55A, the semiconductor device 55B of the fifth preferred embodiment is characterized in that a P-type semiconductor region group 34G is provided instead of the P-type semiconductor region 34. Specifically, the P-type semiconductor regions 34G and 35 in a pair correspond to a P-type semiconductor region and a surrounding P-type semiconductor region in the semiconductor device 55B according to the second aspect of the fifth preferred embodiment.

The P-type semiconductor regions 34G and 35 in a pair forming the surrounding P-type semiconductor region is provided in such a manner as to surround the periphery of the N-type semiconductor region 21 as the first N-type semiconductor region in a plan view, and the P-type semiconductor region group 34G is provided between the N-type semiconductor region 21 and the N-type semiconductor region 22 in a plan view.

The P-type semiconductor region group 34G functions as a first partially surrounding P-type semiconductor region provided in a part of the peripheral region 61 as the first peripheral region of the N-type semiconductor region 21.

The P-type semiconductor region group 34G is composed of a plurality of P-type partial semiconductor regions 44 provided separately from each other. A P-type impurity concentration in each of the P-type partial semiconductor regions 44 of the P-type semiconductor region group 34G is set higher than a P-type impurity concentration in the P-type semiconductor layer 1. The P-type semiconductor region group 34G has a sectional configuration similar to that of the P-type semiconductor region 34 of the first aspect.

A relay interconnect line 26 electrically connected to each of the P-type partial semiconductor regions 44 is provided in the P-type semiconductor region group 34G. The relay interconnect line 26 is electrically connected to the interconnect line L1 through the node P1.

Thus, the power supply voltage V1 from the power supply 11 is applied through the relay interconnect line 26 to each of the P-type partial semiconductor regions 44 forming the P-type semiconductor region group 34G.

Like in the first aspect, the P-type semiconductor region 35 functions as a second partially surrounding P-type semiconductor region provided in the peripheral region 62 of the N-type semiconductor region 21.

The P-type semiconductor region group 34G as the first partially surrounding P-type semiconductor region and the P-type semiconductor region 35 as the second partially surrounding P-type semiconductor region are provided separately from each other. Thus, the clearance regions 65 and 66 are present between the P-type semiconductor region group 34G and the P-type semiconductor region 35.

In addition, in the P-type partial semiconductor regions 44 forming the P-type semiconductor region group 34G as a P-type semiconductor region group for partial surrounding, a gap Δ44 is present between the P-type partial semiconductor regions 44, 44 adjacent to each other.

As described above, the P-type semiconductor regions 34G and 35 in a pair are provided in such a manner as to surround the periphery of the N-type semiconductor region 21 while the clearance regions 65 an 66 and a plurality of the gaps A44 are opened in a plan view.

In the semiconductor device 55B of the second aspect of the fifth preferred embodiment having the above-described configuration, the power supply voltage V1 to be applied to the P-type semiconductor region group 34G and the power supply voltage V3 to be applied to the P-type semiconductor region 35 are set lower than the power supply voltage V2 to be applied to the N-type semiconductor region 21. This allows application of a reverse bias between each of the P-type semiconductor regions 34G and 35 in a pair and the N-type high-breakdown voltage isolation region 2.

As a result, the semiconductor device 55B of the second aspect of the fifth preferred embodiment achieves effects comparable to those of the first preferred embodiment and the second preferred embodiment.

In addition, the P-type semiconductor regions 34G and 35 in a pair forming the surrounding P-type semiconductor region are provided in such a manner as to surround the periphery of the N-type semiconductor region 21 including the peripheral regions 61 and 62 in a plan view. Thus, the above-described depletion layer is a surrounding depletion layer surrounding the N-type semiconductor region 21.

As a result, the semiconductor device 55B according to the second aspect of the fifth preferred embodiment achieves effects comparable to those achieved by the semiconductor device 55A of the first aspect.

In addition, as all the P-type partial semiconductor regions 44 of the P-type semiconductor region group 34G as the P-type semiconductor region group for partial surrounding are arranged separately from each other, it is possible to relax an electric field in the peripheral region 61 of the N-type semiconductor region 21 on the basis of each local and partial depletion layer corresponding to each of the plurality of P-type partial semiconductor regions 44.

As a result, in the semiconductor device 55B according to the second aspect of the fifth preferred embodiment, it is possible to adjust a cathode voltage of the diode D4 by adjusting the gap Δ44 between the P-type partial semiconductor regions 44 adjacent to each other of the plurality of P-type partial semiconductor regions 44 belonging to the P-type semiconductor region group 34G. This accordingly makes it possible to encourage improvement in a degree of freedom in making design in the semiconductor device 55B in terms of a circuit, layout, and others.

In the semiconductor device 55B, the P-type semiconductor region group 34G composed of the P-type partial semiconductor regions 44 functions as the first partially surrounding P-type semiconductor region provided in the peripheral region 61, and the P-type semiconductor region 35 having a single structure functions as the second partially surrounding P-type semiconductor region provided in the peripheral region 62.

This configuration may be reversed to employ a first modification where the P-type semiconductor region 34 having a single structure functions as the first partially surrounding P-type semiconductor region provided in the peripheral region 61, and a P-type semiconductor region group composed of a plurality of P-type partial semiconductor regions functions as the second partially surrounding P-type semiconductor region provided in the peripheral region 62.

In the first modification, a relay interconnect line for the modification electrically connected to each of the P-type partial semiconductor regions is provided, and the power supply voltage V3 is applied from the power supply 13 to the P-type semiconductor region group through the relay interconnect line for the modification. Thus, in the first modification, it is possible to relax an electric field in the peripheral region 62 of the N-type semiconductor region 21 on the basis of each local and partial depletion layer.

A second modification may also be employed where each of the first and second partially surrounding P-type semiconductor regions is configured as a P-type semiconductor region group composed of a plurality of P-type partial semiconductor regions.

As described above, the second aspect of the fifth preferred embodiment includes the first and second modifications, and at least one of the first and second partially surrounding P-type semiconductor regions is configured as a P-type semiconductor region group composed of a plurality of P-type partial semiconductor regions.

### Sixth Preferred Embodiment

### (First Aspect)

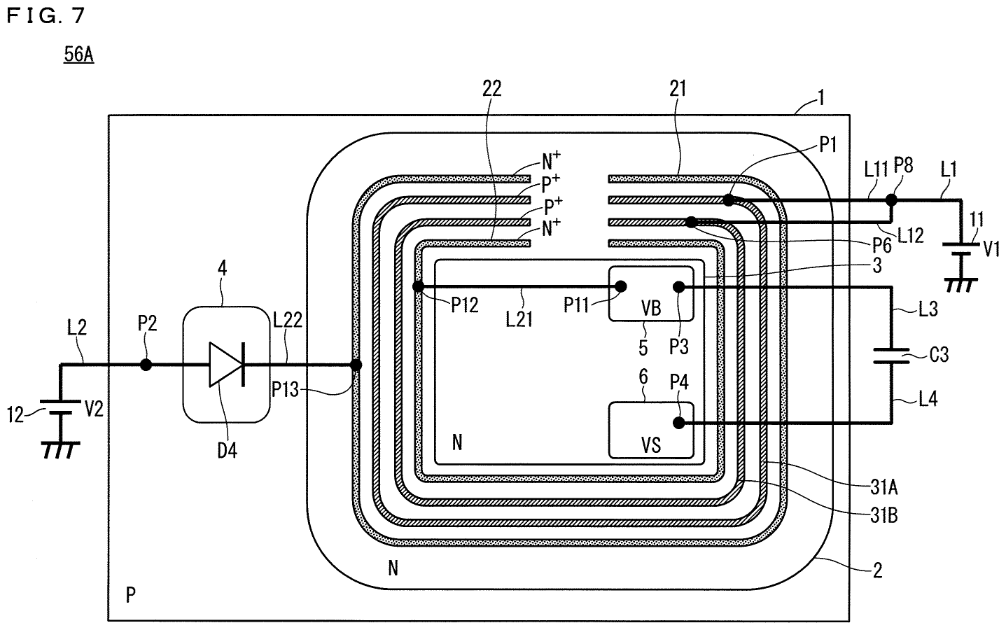

FIG. 7 is an explanatory view schematically showing a planar configuration of a semiconductor device 56A according to a first aspect of a sixth preferred embodiment of the present disclosure.

As shown in FIG. 7, like those of the first preferred embodiment to the fourth preferred embodiment, the semiconductor device 56A according to the first aspect of the sixth preferred embodiment includes a P-type semiconductor layer 1, an N-type high-breakdown voltage isolation region 2, an N-type high-potential region 3, and a diode region 4 provided on the P-type semiconductor layer 1, power supplies 11 and 12, and a capacitor C3 that function as principal components of the semiconductor device 56A.

In the following, structures similar to those of the first preferred embodiment and the second preferred embodiment shown in FIGS. 1 and 2 will be given the same signs and descriptions thereof will be omitted as appropriate, and characteristic parts of the semiconductor device 56A of the sixth preferred embodiment will be described mainly.

Compared to those of the first preferred embodiment and the second preferred embodiment, the semiconductor device 56A of the sixth preferred embodiment is characterized in that P-type semiconductor regions 31A and 31B forming a plurality of P-type semiconductor regions are provided instead of the P-type semiconductor region 31.

Specifically, the P-type semiconductor regions 31A and 31B correspond to a P-type semiconductor region in the semiconductor device 56A according to the first aspect of the sixth preferred embodiment.

In the semiconductor device 56A, the P-type semiconductor regions 31A and 31B are provided as a plurality of the P-type semiconductor regions provided separately from each other. Specifically, the plurality of P-type semiconductor regions in the semiconductor device 56A includes the P-type semiconductor region 31A as a first P-type semiconductor region and the P-type semiconductor region 31B as a second P-type semiconductor region.

Each of the P-type semiconductor regions 31A and 31B as the plurality of P-type semiconductor regions is arranged between the N-type semiconductor region 21 and the N-type semiconductor region 22 in a plan view. Thus, the N-type semiconductor region 22 is arranged closer to the N-type high-potential region 3 than the N-type semiconductor region 21 and the P-type semiconductor regions 31A and 31B. Furthermore, each of the P-type semiconductor regions 31A and 31B is arranged between the N-type semiconductor region 21 and the N-type high-potential region 3 in a plan view.

The P-type semiconductor regions 31A and 31B are provided independently of each other and selectively in the upper layer part of the N-type high-breakdown voltage isolation region 2. The P-type semiconductor regions 31A and 31B do not have contact relationship therebetween. A P-type impurity concentration in each of the P-type semiconductor regions 31A and 31B is set higher than a P-type impurity concentration in the P-type semiconductor layer 1.

The P-type semiconductor regions 31A and 31B shown in FIG. 7 have sectional configurations corresponding to those of the p⁺-layer 213 and the p⁺-layer 214 shown in FIG. 13, for example.

An entire region of each of the P-type semiconductor regions 31A and 31B is arranged between the N-type semiconductor region 21 and the N-type semiconductor region 22 in a plan view.

Of the P-type semiconductor regions 31A and 31B, the P-type semiconductor region 31A is provided external to the P-type semiconductor region 31B. Specifically, the P-type semiconductor region 31A is arranged closer to the N-type semiconductor region 21 than the P-type semiconductor region 31B, and the P-type semiconductor region 31B is arranged closer to the N-type semiconductor region 22 than the P-type semiconductor region 31A.

The P-type semiconductor region 31A includes a first P-type parallel region parallel to three sides of the N-type high-potential region 3 in a plan view. The three sides correspond to the right side, the left side, and the lower side of the N-type high-potential region 3 shown in FIG. 7. The first P-type parallel region further includes a region parallel to a part of the upper side of the N-type high-potential region 3.

As described above, the P-type semiconductor region 31A includes the first P-type parallel region parallel to the at least three sides of the N-type high-potential region 3 in a plan view. The at least three sides are common to the N-type semiconductor regions 21 and 22 and the P-type semiconductor region 31A. Thus, the P-type semiconductor region 31A surrounds the N-type high-potential region 3 over a region exceeding ¾ of the outer perimeter thereof in a plan view.

Likewise, the P-type semiconductor region 31B includes a second P-type parallel region parallel to the three sides of the N-type high-potential region 3 in a plan view. The three sides correspond to the right side, the left side, and the lower side of the N-type high-potential region 3 shown in FIG. 7. The second P-type parallel region further includes a region parallel to a part of the upper side of the N-type high-potential region 3.

As described above, the P-type semiconductor region 31B includes the second P-type parallel region parallel to the at least three sides of the N-type high-potential region 3 in a plan view. The at least three sides are common to the N-type semiconductor regions 21 and 22, and the P-type semiconductor regions 31A and 31B. Thus, the P-type semiconductor region 31B surrounds the N-type high-potential region 3 over a region exceeding ¾ of the outer perimeter thereof in a plan view.

As described above, in the first aspect of the sixth preferred embodiment, the first P-type parallel region of the P-type semiconductor region 31A and the second P-type parallel region of the P-type semiconductor region 31B are provided as P-type parallel regions of the P-type semiconductor regions.

As described above, an entire area of each of the P-type semiconductor regions 31A and 31B is arranged between the N-type semiconductor region 21 and the N-type semiconductor region 22 in a plan view. Thus, each of the first and second P-type parallel regions of the P-type semiconductor regions 31A and 31B respectively is arranged between the first N-type parallel region of the N-type semiconductor region 21 and the second N-type parallel region of the N-type semiconductor region 22 in a plan view.

The power supply voltage V1 from the power supply 11 is applied to the P-type semiconductor region 31A through the interconnect line L1 and an interconnect line L11, and is applied to the P-type semiconductor region 31B through the interconnect line L1 and an interconnect line L12. The interconnect line L11 and the interconnect line L12 branch from a node P8 on the interconnect line L1. One end of the interconnect line L11 is electrically connected to the node P1 on the P-type semiconductor region 31A. One end of the interconnect line L12 is electrically connected to a node P6 on the P-type semiconductor region 31B. The other end of each of the interconnect lines L11 and L12 is electrically connected to the intermediary node P8.

Thus, in the semiconductor device 56A according to the first aspect of the sixth preferred embodiment, the power supply voltage V1 as the first voltage is applied commonly to the P-type semiconductor regions 31A and 31B as the first and second P-type semiconductor regions.

In the semiconductor device 56A according to the first aspect of the sixth preferred embodiment, the power supply voltage V1 to be applied commonly to the P-type semiconductor regions 31A and 31B is set lower than the power supply voltage V2 to be applied to the N-type semiconductor region 21. This allows application of a reverse bias between each of the P-type semiconductor regions 31A and 31B and the N-type high-breakdown voltage isolation region 2.

Thus, using a depletion layer generated at an interface between each of the first and second P-type parallel regions of the P-type semiconductor regions 31A and 31B respectively and the N-type high-breakdown voltage isolation region 2, it is possible to relax an electric field in the periphery of the N-type semiconductor region 21 electrically connected to the cathode of the diode D4.

As a result, the semiconductor device 56A according to the first aspect of the sixth preferred embodiment achieves effects comparable to those of the first preferred embodiment and the second preferred embodiment.

Furthermore, in the semiconductor device 56A according to the first aspect of the sixth preferred embodiment, providing a plurality of the P-type semiconductor regions (P-type semiconductor regions 31A and 31B) separately from each other as the P-type semiconductor region makes it possible to relax an electric field stepwise in the periphery of the N-type semiconductor region 21.

In the semiconductor device 56A of the sixth preferred embodiment, providing the P-type semiconductor regions 31A and 31B as the first and second P-type semiconductor regions makes it possible to relax an electric field in two steps in the periphery of the N-type semiconductor region 21.

In addition, as the power supply voltage V1 as the first voltage is applied commonly to the P-type semiconductor regions 31A and 31B, it is possible to configure the semiconductor device 56A of the sixth preferred embodiment without adding a new power supply.

### (Second Aspect)

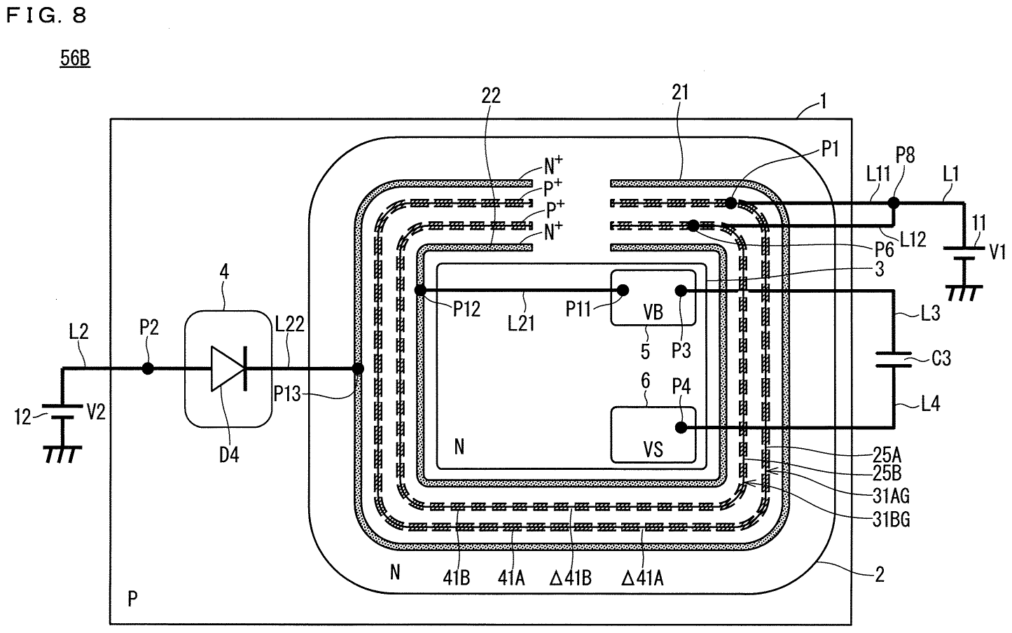

FIG. 8 is an explanatory view schematically showing a planar configuration of a semiconductor device 56B according to a second aspect of the sixth preferred embodiment of the present disclosure.

As shown in FIG. 8, like that of the first aspect of the sixth preferred embodiment shown in FIG. 7, the semiconductor device 56B according to the second aspect of the sixth preferred embodiment includes a P-type semiconductor layer 1, an N-type high-breakdown voltage isolation region 2, an N-type high-potential region 3, and a diode region 4 provided on the P-type semiconductor layer 1, power supplies 11 and 12, and a capacitor C3 that function as principal components of the semiconductor device 56B.

In the following, structures similar to those of the first aspect of the sixth preferred embodiment shown in FIG. 7 will be given the same signs and descriptions thereof will be omitted as appropriate, and characteristic parts of the semiconductor device 56B according to the second aspect of the sixth preferred embodiment will be described mainly.

Compared to that of the first aspect of the sixth preferred embodiment, the semiconductor device 56B of the sixth preferred embodiment is characterized in that P-type semiconductor region groups 31AG and 31BG forming a plurality of P-type semiconductor regions are provided instead of the P-type semiconductor regions 31A and 31B. Specifically, the P-type semiconductor region groups 31AG and 31BG correspond to a P-type semiconductor region in the semiconductor device 56B according to the second aspect of the sixth preferred embodiment.

In the semiconductor device 56B, the P-type semiconductor region groups 31AG and 31BG are provided as a plurality of the P-type semiconductor regions provided separately from each other. Specifically, the plurality of P-type semiconductor regions in the semiconductor device 56B includes the P-type semiconductor region group 31AG as a first P-type semiconductor region group and the P-type semiconductor region group 31BG as a second P-type semiconductor region group.

The P-type semiconductor region group 31AG and the P-type semiconductor region group 31BG are provided independently of each other and selectively in the upper layer part of the N-type high-breakdown voltage isolation region 2.

The P-type semiconductor region group 31AG is composed of a plurality of P-type partial semiconductor regions 41A provided separately from each other. The P-type semiconductor region group 31BG is composed of a plurality of P-type partial semiconductor regions 41B provided separately from each other. A P-type impurity concentration in each of the P-type partial semiconductor regions 41A and in each of the P-type partial semiconductor regions 41B is set higher than a P-type impurity concentration in the P-type semiconductor layer 1.

In the P-type partial semiconductor regions 41A forming the P-type semiconductor region group 31AG, a gap Δ41A is present between the P-type partial semiconductor regions 41A, 41A adjacent to each other. In the P-type partial semiconductor regions 41B forming the P-type semiconductor region group 31BG, a gap A41B is present between the P-type partial semiconductor regions 41B, 41B adjacent to each other.

The P-type semiconductor region group 31AG has a configuration similar to that of the P-type semiconductor region 31A of the first aspect except that the P-type semiconductor region group 31AG is composed of the P-type partial semiconductor regions 41A. The P-type semiconductor region group 31BG has a configuration similar to that of the P-type semiconductor region 31B of the first aspect except that the P-type semiconductor region group 31BG is composed of the P-type partial semiconductor regions 41B.

A relay interconnect line 25A electrically connected to each of the P-type partial semiconductor regions 41A is provided in the P-type semiconductor region group 31AG. The relay interconnect line 25A is electrically connected to one end of the interconnect line L11 through the node P1.

Thus, the power supply voltage V1 from the power supply 11 is applied through the relay interconnect line 25A to each of the P-type partial semiconductor regions 41A forming the P-type semiconductor region group 31AG.

A relay interconnect line 25B electrically connected to each of the P-type partial semiconductor regions 41B is provided in the P-type semiconductor region group 31BG. The relay interconnect line 25B is electrically connected to one end of the interconnect line L12 through the node P6.

Thus, the power supply voltage V1 from the power supply 11 is applied through the relay interconnect line 25B to each of the P-type partial semiconductor regions 41B forming the P-type semiconductor region group 31BG.

In the semiconductor device 56B according to the second aspect of the sixth preferred embodiment, the power supply voltage V1 to be applied commonly to the P-type semiconductor region groups 31AG and 31BG is set lower than the power supply voltage V2 to be applied to the N-type semiconductor region 21. This allows application of a reverse bias between each of the P-type semiconductor region groups 31AG and 31BG and the N-type high-breakdown voltage isolation region 2.

Thus, using a depletion layer generated at an interface between each of the first and second P-type parallel regions of the P-type semiconductor region groups 31AG and 31BG respectively and the N-type high-breakdown voltage isolation region 2, it is possible to relax an electric field in the periphery of the N-type semiconductor region 21 electrically connected to the cathode of the diode D4.

As a result, the semiconductor device 56B according to the second aspect of the sixth preferred embodiment achieves effects comparable to those of the first preferred embodiment and the second preferred embodiment.

Furthermore, in the semiconductor device 56B according to the second aspect of the sixth preferred embodiment, providing a plurality of the P-type semiconductor regions (P-type semiconductor region groups 31AG and 31BG) separately from each other as the P-type semiconductor region makes it possible to relax an electric field stepwise in the periphery of the N-type semiconductor region 21.

In the semiconductor device 56B of the sixth preferred embodiment, providing the P-type semiconductor region groups 31AG and 31BG as the first and second P-type semiconductor regions makes it possible to relax an electric field in two steps in the periphery of the N-type semiconductor region 21.

In addition, as the power supply voltage V1 as the first voltage is applied commonly to the P-type semiconductor region groups 31AG and 31BG, it is possible to configure the semiconductor device 56B of the sixth preferred embodiment without adding a new power supply.

Furthermore, as all the P-type partial semiconductor regions 41A of the P-type semiconductor region group 31AG are arranged separately from each other and all the P-type partial semiconductor regions 41B of the P-type semiconductor region group 31BG are arranged separately from each other, it is possible to relax an electric field in the periphery of the N-type semiconductor region 21 on the basis of each local and partial depletion layer.

As a result, the semiconductor device 56B according to the second aspect of the sixth preferred embodiment achieves effects comparable to those of the semiconductor device 53 of the third preferred embodiment shown in FIG. 3 in terms of the P-type semiconductor region groups 31AG and 31BG.

In the configuration of the semiconductor device 56B described above, the P-type semiconductor regions 31A and 31B of the first aspect are replaced by the P-type semiconductor region groups 31AG and 31BG respectively.

A first modification and a second embodiment may be employed in addition to the above configuration. In the first modification, only the P-type semiconductor region 31A of the P-type semiconductor regions 31A and 31B is replaced by the P-type semiconductor region group 31AG. In the second modification, only the P-type semiconductor region 31B of the P-type semiconductor regions 31A and 31B is replaced by the P-type semiconductor region group 31BG.

Specifically, in the second aspect of the sixth preferred embodiment, at least one of the first and second P-type semiconductor regions is configured as a P-type semiconductor region group composed of a plurality of P-type partial semiconductor regions.

### (Third Aspect)

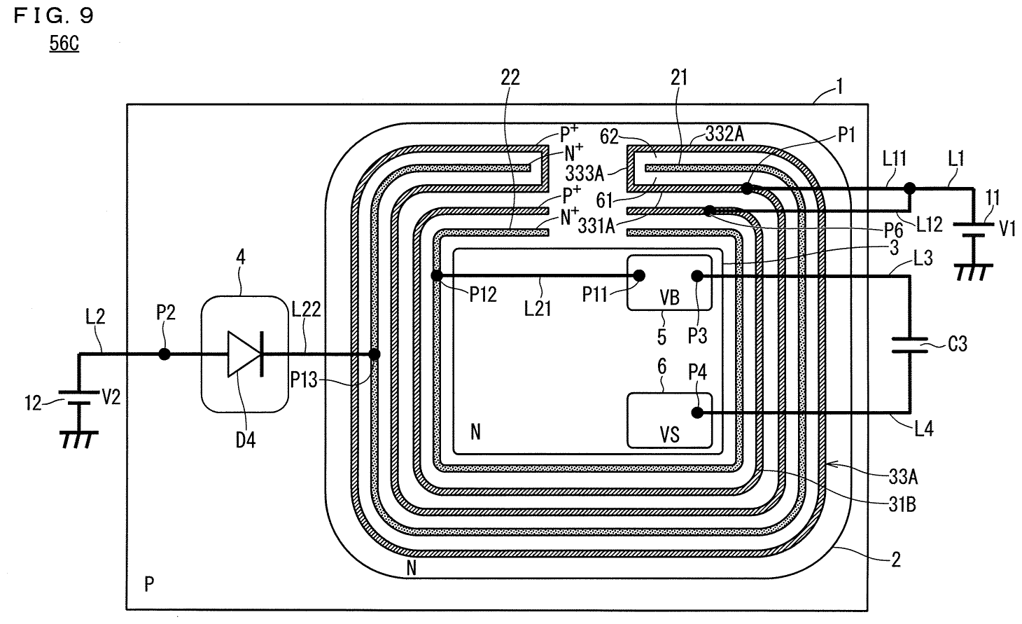

FIG. 9 is an explanatory view schematically showing a planar configuration of a semiconductor device 56C according to a third aspect of the sixth preferred embodiment of the present disclosure.

As shown in FIG. 9, like that of the first aspect of the sixth preferred embodiment shown in FIG. 7, the semiconductor device 56C according to the third aspect of the sixth preferred embodiment includes a P-type semiconductor layer 1, an N-type high-breakdown voltage isolation region 2, an N-type high-potential region 3, and a diode region 4 provided on the P-type semiconductor layer 1, power supplies 11 and 12, and a capacitor C3 that function as principal components of the semiconductor device 56C.

In the following, structures similar to those of the first aspect of the sixth preferred embodiment shown in FIG. 7 will be given the same signs and descriptions thereof will be omitted as appropriate, and characteristic parts of the semiconductor device 56C according to the third aspect of the sixth preferred embodiment will be described mainly.

Compared to that of the first aspect of the sixth preferred embodiment, the semiconductor device 56C of the sixth preferred embodiment is characterized in that a P-type semiconductor region 33A as a completely surrounding P-type semiconductor region is provided instead of the P-type semiconductor region 31A. Specifically, the P-type semiconductor regions 33A and the P-type semiconductor region 31B correspond to a P-type semiconductor region in the semiconductor device 56C of the third aspect.

Like the P-type semiconductor region 33 of the fourth preferred embodiment, the P-type semiconductor region 33A includes an internal P-type parallel region 331A formed in the peripheral region 61, an external P-type parallel region 332A formed in the peripheral region 62, and a connection region 333A connecting the internal P-type parallel region 331A and the external P-type parallel region 332A to each other. The internal P-type parallel region 331A has an equivalent configuration to the internal P-type parallel region 331 shown in FIG. 4. The external P-type parallel region 332A has an equivalent configuration to the external P-type parallel region 332 shown in FIG. 4.

The P-type semiconductor region 33A as the completely surrounding P-type semiconductor region is provided in such a manner as to surround the periphery of the N-type semiconductor region 21 as the first N-type semiconductor region without a gap in a plan view.

Like the P-type semiconductor region 33 in the semiconductor device 54 of the fourth preferred embodiment shown in FIG. 4, an entire area of the internal P-type parallel region 331A of the P-type semiconductor region 33A is arranged between the N-type semiconductor region 21 and the N-type semiconductor region 22. Thus, the internal P-type parallel region 331A is arranged between the first N-type parallel region of the N-type semiconductor region 21 and the second N-type parallel region of the N-type semiconductor region 22 in a plan view.

The power supply voltage V1 from the power supply 11 is applied to the P-type semiconductor region 33A through the interconnect line L1 and the interconnect line L11. Specifically, the node P1 on the P-type semiconductor region 33A is electrically connected to one end of the interconnect line L11.

The P-type semiconductor region 33A corresponds to the P-type semiconductor region 31A of the first aspect, and includes the internal P-type parallel region 331A and the external P-type parallel region 332A as a first P-type parallel region.

In the semiconductor device 56C according to the third aspect of the sixth preferred embodiment, the power supply voltage V1 to be applied commonly to the P-type semiconductor region 33A and the P-type semiconductor region 31B is set lower than the power supply voltage V2 to be applied to the N-type semiconductor region 21. This allows application of a reverse bias between each of the P-type semiconductor region 33A and the P-type semiconductor region 31B and the N-type high-breakdown voltage isolation region 2.

Thus, using a depletion layer generated at an interface between each of the first and second P-type parallel regions of the P-type semiconductor region 33A and the P-type semiconductor region 31B respectively and the N-type high-breakdown voltage isolation region 2, it is possible to relax an electric field in the periphery of the N-type semiconductor region 21 electrically connected to the cathode of the diode D4.

As a result, the semiconductor device 56C according to the third aspect of the sixth preferred embodiment achieves effects comparable to those of the first preferred embodiment and the second preferred embodiment.

Furthermore, in the semiconductor device 56C according to the third aspect of the sixth preferred embodiment, providing a plurality of the P-type semiconductor regions (P-type semiconductor region 33A and P-type semiconductor region 31B) separately from each other as the P-type semiconductor region makes it possible to relax an electric field stepwise in the periphery of the N-type semiconductor region 21.

In the semiconductor device 56C of the sixth preferred embodiment, providing the P-type semiconductor region 33A and the P-type semiconductor region 31B as the first and second P-type semiconductor regions makes it possible to relax an electric field in two steps in the periphery of the N-type semiconductor region 21.

In addition, as the power supply voltage V1 as the first voltage is applied commonly to the P-type semiconductor region 33A and the P-type semiconductor region 31B, it is possible to configure the semiconductor device 56C of the sixth preferred embodiment without adding a new power supply.

Furthermore, as the P-type semiconductor region 33A as the completely surrounding P-type semiconductor region is provided in such a manner as to surround the periphery of the N-type semiconductor region 21 without a gap in a plan view, effects comparable to those of the semiconductor device 54 of the fourth preferred embodiment are achieved in terms of the P-type semiconductor region 33A.

A first modification or a second modification may be employed in the semiconductor device 56C. In the first modification, the P-type semiconductor region 33A is replaced by a P-type semiconductor region group composed of a plurality of P-type partial semiconductor regions. In the second modification, the P-type semiconductor region 31B is replaced by the P-type semiconductor region group 31BG.

A third modification may also be employed where the P-type semiconductor region 31B is replaced by a completely surrounding P-type semiconductor region surrounding the P-type semiconductor region 33A in a plan view. Specifically, the third modification may have a configuration where first and second completely surrounding P-type semiconductor regions are provided as two regions surrounding the N-type semiconductor region 21.

### Seventh Preferred Embodiment

### (First Aspect)

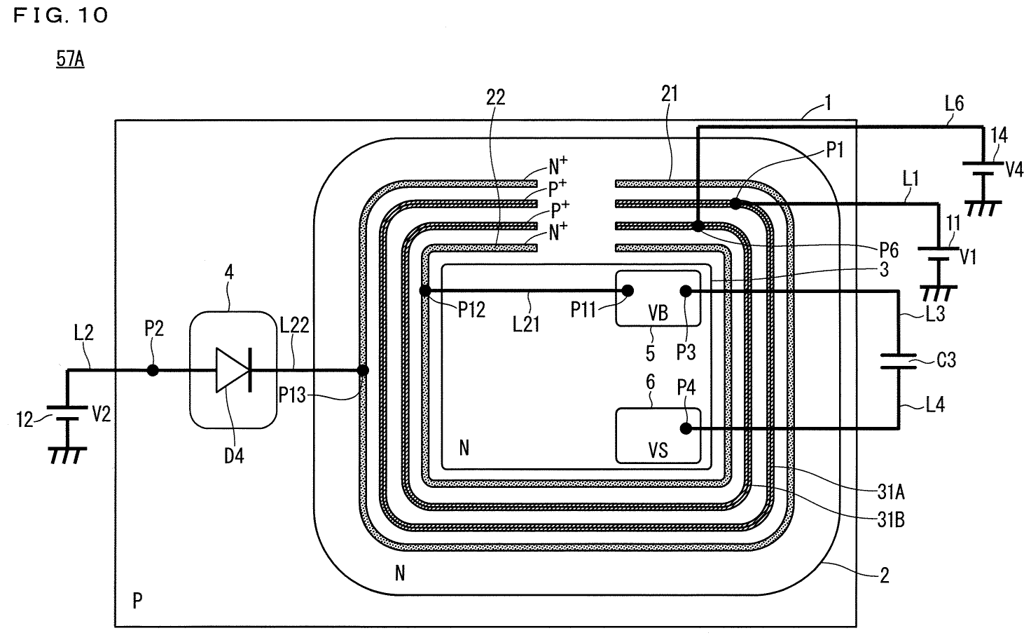

FIG. 10 is an explanatory view schematically showing a planar configuration of a semiconductor device 57A according to a first aspect of a seventh preferred embodiment of the present disclosure.

As shown in FIG. 10, the semiconductor device 57A according to the first aspect of the seventh preferred embodiment includes a P-type semiconductor layer 1, an N-type high-breakdown voltage isolation region 2, an N-type high-potential region 3, and a diode region 4 provided on the P-type semiconductor layer 1, power supplies 11 and 12, a power supply 14, and a capacitor C3 that function as principal components of the semiconductor device 57A.

In the following, structures similar to those of the first aspect of the sixth preferred embodiment shown in FIG. 7 will be given the same signs and descriptions thereof will be omitted as appropriate, and characteristic parts of the semiconductor device 57A of the first aspect of the seventh preferred embodiment will be described mainly.

Compared to that of the first aspect of the sixth preferred embodiment, the semiconductor device 57A of the first aspect of the seventh preferred embodiment is characterized in that it further includes the power supply 14 as a fourth power supply to supply a power supply voltage V4 as a fourth voltage. The power supply voltage V4 as the fourth voltage is set lower than the power supply voltage V2 as the second voltage. To be precise, defining that a drop voltage of the diode D4 as VF, the power supply voltage V4 is set in such a manner as to satisfy the following: {V4<(V2−VF)}.

A magnitude relationship between the power supply voltage V1 and the power supply voltage V4 is determined arbitrarily. Specifically, a magnitude relationship between the power supply voltage V1 and the power supply voltage V4 is arbitrarily settable within a range in which {V1<V2, V4<V2} is satisfied.

The power supply voltage V4 as the fourth voltage is applied to the P-type semiconductor region 31B as the second P-type semiconductor region through an interconnect line L6. Specifically, the node P6 on the P-type semiconductor region 31B is electrically connected to one end of the interconnect line L6, and a positive pole of the power supply 14 is connected to the other end of the interconnect line L6. A negative pole of the power supply 14 is electrically connected to a ground level as a reference potential. The power supply voltage V4 from the power supply 14 is not supplied to the P-type semiconductor layer 1.

In the semiconductor device 57A according to the first aspect of the seventh preferred embodiment, the power supply voltage V1 to be applied to the P-type semiconductor region 31A and the power supply voltage V4 to be applied to the P-type semiconductor region 31B are set lower than the power supply voltage V2 to be applied to the N-type semiconductor region 21. This allows application of a reverse bias between each of the P-type semiconductor regions 31A and 31B and the N-type high-breakdown voltage isolation region 2.

Thus, using a depletion layer generated at an interface between each of the first and second P-type parallel regions of the P-type semiconductor regions 31A and 31B respectively and the N-type high-breakdown voltage isolation region 2, it is possible to relax an electric field in the periphery of the N-type semiconductor region 21 electrically connected to the cathode of the diode D4.

As a result, the semiconductor device 57A according to the first aspect of the seventh preferred embodiment achieves effects comparable to those of the first preferred embodiment and the second preferred embodiment.

Furthermore, by providing a plurality of the P-type semiconductor regions (P-type semiconductor regions 31A and 31B) separately from each other as the P-type semiconductor region, the semiconductor device 57A according to the first aspect of the seventh preferred embodiment achieves effects comparable to those achieved by the semiconductor device 56A according to the first aspect of the sixth preferred embodiment.

Furthermore, in the semiconductor device 57A according to the first aspect of the seventh preferred embodiment, the power supply voltage V1 as the first voltage is applied to the P-type semiconductor region 31A as the first P-type semiconductor region, the power supply voltage V4 as the fourth voltage is applied to the P-type semiconductor region 31B as the second P-type semiconductor region, and the power supply 11 and the power supply 14 as the first and fourth power supplies are provided independently of each other. Specifically, the power supply voltage V1 and the power supply voltage V4 are independent of each other. This allows the power supply voltage V1 and the power supply voltage V4 to be set individually.

Thus, in the semiconductor device 57A according to the first aspect of the seventh preferred embodiment, an electric field in the periphery of the N-type semiconductor region 21 is relaxed gently in two steps, making it possible to adjust an electric field distribution in the periphery of the N-type semiconductor region 21 comparatively easily.

### (Second Aspect)

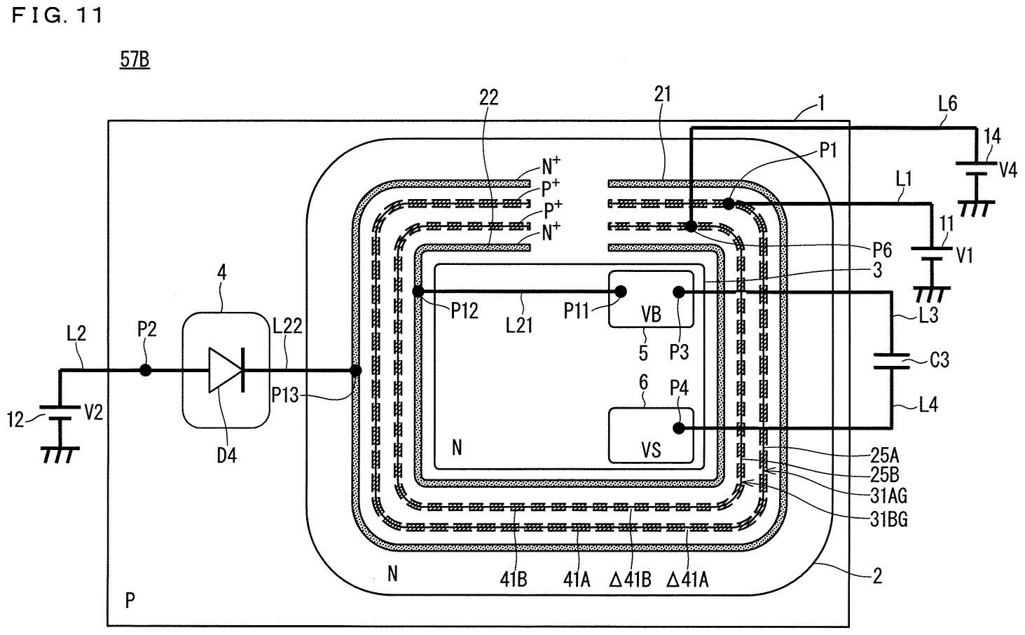

FIG. 11 is an explanatory view schematically showing a planar configuration of a semiconductor device 57B according to a second aspect of the seventh preferred embodiment of the present disclosure.

As shown in FIG. 11, the semiconductor device 57B according to the second aspect of the seventh preferred embodiment includes a P-type semiconductor layer 1, an N-type high-breakdown voltage isolation region 2, an N-type high-potential region 3, and a diode region 4 provided on the P-type semiconductor layer 1, power supplies 11 and 12, a power supply 14, and a capacitor C3 that function as principal components of the semiconductor device 57B.

In the following, structures similar to those of the second aspect of the sixth preferred embodiment shown in FIG. 8 will be given the same signs and descriptions thereof will be omitted as appropriate, and characteristic parts of the semiconductor device 57B of the second aspect of the seventh preferred embodiment will be described mainly.

Like that of the first aspect of the seventh preferred embodiment shown in FIG. 10, the semiconductor device 57B of the second aspect of the seventh preferred embodiment is characterized in that it further includes the power supply 14 as the fourth power supply to supply the power supply voltage V4 as the fourth voltage. The power supply voltage V4 is set lower than the power supply voltage V2.

The power supply voltage V4 as the fourth voltage is applied to the P-type semiconductor region group 31BG as the second P-type semiconductor region through the interconnect line L6. Specifically, the node P6 on the P-type semiconductor region group 31BG is electrically connected to one end of the interconnect line L6, and the positive pole of the power supply 14 is connected to the other end of the interconnect line L6.

In the semiconductor device 57B according to the second aspect of the seventh preferred embodiment, the power supply voltage V1 to be applied to the P-type semiconductor region group 31AG and the power supply voltage V4 to be applied to the P-type semiconductor region group 31BG are set lower than the power supply voltage V2 to be applied to the N-type semiconductor region 21. This allows application of a reverse bias between each of the P-type semiconductor region groups 31AG and 31BG and the N-type high-breakdown voltage isolation region 2.

Thus, using a depletion layer generated at an interface between each of the first and second P-type parallel regions of the P-type semiconductor region groups 31AG and 31BG respectively and the N-type high-breakdown voltage isolation region 2, it is possible to relax an electric field in the periphery of the N-type semiconductor region 21 electrically connected to the cathode of the diode D4.

As a result, the semiconductor device 57B according to the second aspect of the seventh preferred embodiment achieves effects comparable to those of the first preferred embodiment and the second preferred embodiment.

Furthermore, by providing a plurality of the P-type semiconductor regions (P-type semiconductor region groups 31AG and 31BG) separately from each other as the P-type semiconductor region, the semiconductor device 57B according to the second aspect of the seventh preferred embodiment achieves effects comparable to those achieved by the semiconductor device 56B according to the second aspect of the sixth preferred embodiment.

In addition, in the semiconductor device 57B according to the second aspect of the seventh preferred embodiment, the power supply voltage V1 is applied to the P-type semiconductor region group 31AG, the power supply voltage V4 is applied to the P-type semiconductor region group 31BG, and the power supply 11 and the power supply 14 are provided independently of each other. This allows the power supply voltage V1 and the power supply voltage V4 to be set individually.

Thus, like in the first aspect of the seventh preferred embodiment, in the semiconductor device 57B according to the second aspect of the seventh preferred embodiment, an electric field in the periphery of the N-type semiconductor region 21 is relaxed gently in two steps, making it possible to adjust an electric field distribution in the periphery of the N-type semiconductor region 21 comparatively easily.

Like in the second aspect of the sixth preferred embodiment, in the second aspect of the seventh preferred embodiment, at least one of the first and second P-type semiconductor regions is configured as a P-type semiconductor region group composed of a plurality of P-type partial semiconductor regions.

### (Third Aspect)

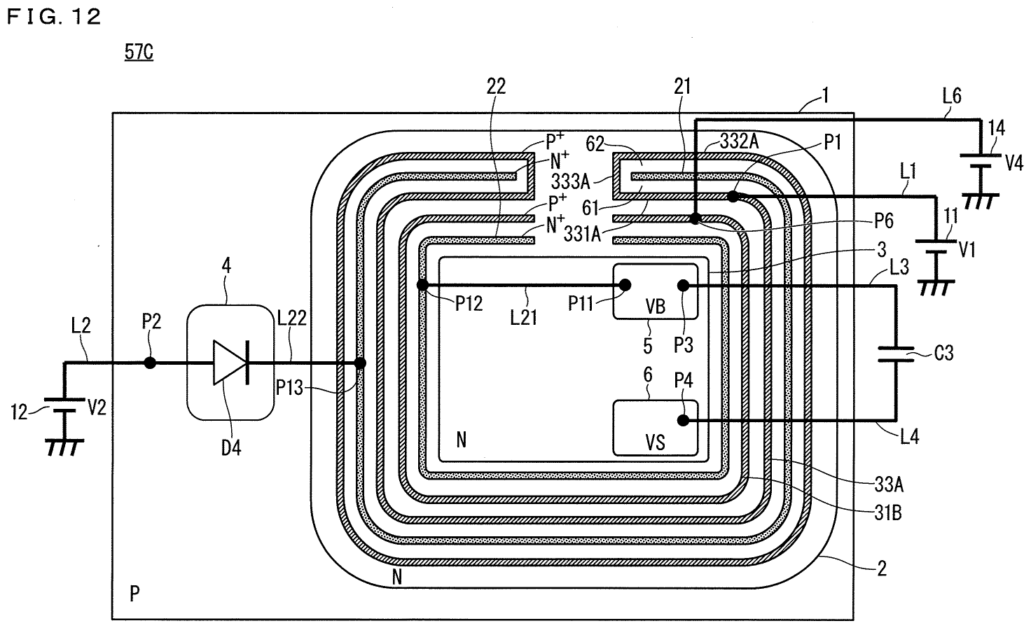

FIG. 12 is an explanatory view schematically showing a planar configuration of a semiconductor device 57C according to a third aspect of the seventh preferred embodiment of the present disclosure.

As shown in FIG. 12, the semiconductor device 57C according to the third aspect of the seventh preferred embodiment includes a P-type semiconductor layer 1, an N-type high-breakdown voltage isolation region 2, an N-type high-potential region 3, and a diode region 4 provided on the P-type semiconductor layer 1, power supplies 11, 12, a power supply 14, and a capacitor C3 that function as principal components of the semiconductor device 57C.

In the following, structures similar to those of the third aspect of the sixth preferred embodiment shown in FIG. 9 will be given the same signs and descriptions thereof will be omitted as appropriate, and characteristic parts of the semiconductor device 57C of the third aspect of the seventh preferred embodiment will be described mainly.

Like that of the first aspect shown in FIG. 10 and that of the second aspect shown in FIG. 11, the semiconductor device 57C of the third aspect of the seventh preferred embodiment is characterized in that it further includes the power supply 14 as the fourth power supply to supply the power supply voltage V4 as the fourth voltage. The power supply voltage V4 is set lower than the power supply voltage V2.

The power supply voltage V4 as the fourth voltage is applied to the P-type semiconductor region 31B as the second P-type semiconductor region through the interconnect line L6. Specifically, the node P6 on the P-type semiconductor region 31B is electrically connected to one end of the interconnect line L6, and the positive pole of the power supply 14 is connected to the other end of the interconnect line L6.

In the semiconductor device 57C according to the third aspect of the seventh preferred embodiment, the power supply voltage V1 to be applied to the P-type semiconductor region 33A and the power supply voltage V4 to be applied to the P-type semiconductor region 31B are set lower than the power supply voltage V2 to be applied to the N-type semiconductor region 21. This allows application of a reverse bias between each of the P-type semiconductor regions 33A and 31B and the N-type high-breakdown voltage isolation region 2.

Thus, using a depletion layer generated at an interface between each of the first and second P-type parallel regions of the P-type semiconductor region 33A and the P-type semiconductor region 31B respectively and the N-type high-breakdown voltage isolation region 2, it is possible to relax an electric field in the periphery of the N-type semiconductor region 21 electrically connected to the cathode of the diode D4.

As a result, the semiconductor device 57C according to the third aspect of the seventh preferred embodiment achieves effects comparable to those of the first preferred embodiment and the second preferred embodiment.

Furthermore, by providing a plurality of the P-type semiconductor regions (P-type semiconductor region 33A and P-type semiconductor region 31B) separately from each other as the P-type semiconductor region, the semiconductor device 57C according to the third aspect of the seventh preferred embodiment achieves effects comparable to those achieved by the semiconductor device 56C according to the third aspect of the sixth preferred embodiment.

In addition, in the semiconductor device 57C according to the third aspect of the seventh preferred embodiment, the power supply voltage V1 is applied to the P-type semiconductor region 33A, the power supply voltage V4 is applied to the P-type semiconductor region 31B, and the power supply 11 and the power supply 14 are provided independently of each other. Specifically, the power supply voltage V1 and the power supply voltage V4 are independent of each other. This allows the power supply voltage V1 and the power supply voltage V4 to be set individually.

Thus, like in the first and second aspects of the seventh preferred embodiment, in the semiconductor device 57C according to the third aspect of the seventh preferred embodiment, an electric field in the periphery of the N-type semiconductor region 21 is relaxed gently in two steps, making it possible to adjust an electric field distribution in the periphery of the N-type semiconductor region 21 comparatively easily.

Like in the third aspect of the sixth preferred embodiment, in the third aspect of the seventh preferred embodiment, the first to third modifications may be employed as modifications of a combination of the P-type semiconductor region 33A and the P-type semiconductor region 31B.

### <Others>

While the shape of the N-type high-potential region 3 has a quadrangular shape in a plan view in the above-described preferred embodiments, the N-type high-potential region 3 may be formed into a polygonal shape having three or more corners.

The preferred embodiments of the present disclosure can be combined freely, and each preferred embodiment can be modified or omitted, as appropriate, within the range of the disclosure.

### <Appendixes>

The aspects of the present disclosure will be summarized below in Appendixes.

### (Appendix 1)

A semiconductor device comprising:
a P-type semiconductor layer;
an N-type high-potential region provided on the P-type semiconductor layer;
an N-type high-breakdown voltage isolation region provided on the P-type semiconductor layer in such a manner as to surround the N-type high-potential region in a plan view;
a diode region provided on the P-type semiconductor layer independently of the N-type high-breakdown voltage isolation region, and including a diode with an anode to be supplied with a second voltage higher than a first voltage;
a first N-type semiconductor region and a second N-type semiconductor region provided selectively in an upper layer part of the N-type high-breakdown voltage isolation region; and
a P-type semiconductor region provided selectively in the upper layer part of the N-type high-breakdown voltage isolation region and to be supplied with the first voltage lower than the second voltage, wherein
an N-type impurity concentration in each of the first and second N-type semiconductor regions is set higher than an N-type impurity concentration in the N-type high-breakdown voltage isolation region, the first and second N-type semiconductor regions and the P-type semiconductor region are provided in the absence of contact relationship therebetween,
the second N-type semiconductor region is arranged closer to the N-type high-potential region than the first N-type semiconductor region and the P-type semiconductor region,
the P-type semiconductor region is arranged between the first N-type semiconductor region and the N-type high-potential region in a plan view,
the diode has a cathode electrically connected to the first N-type semiconductor region, and
the second N-type semiconductor region is electrically connected to the N-type high-potential region.

### (Appendix 2)

The semiconductor device according to Appendix 1, wherein
the N-type high-potential region has a polygonal shape having three or more corners in a plan view,
the first N-type semiconductor region includes a first N-type parallel region parallel to at least one side of the N-type high-potential region in a plan view,
the second N-type semiconductor region includes a second N-type parallel region parallel to the at least one side of the N-type high-potential region in a plan view,
the P-type semiconductor region includes a P-type parallel region parallel to the at least one side of the N-type high-potential region in a plan view, and
the P-type parallel region is arranged between the first N-type parallel region and the second N-type parallel region in a plan view.

### (Appendix 3)

The semiconductor device according to Appendix 1 or 2, wherein
the P-type semiconductor region includes a P-type semiconductor region group composed of a plurality of P-type partial semiconductor regions provided separately from each other,
the semiconductor device further comprises:
a relay interconnect line electrically connected to each of the plurality of P-type partial semiconductor regions, and
the first voltage is applied to each of the plurality of P-type partial semiconductor regions of the P-type semiconductor region group through the relay interconnect line.

### (Appendix 4)

The semiconductor device according to Appendix 1 or 2, wherein
in the N-type high-breakdown voltage isolation region, a peripheral region of the first N-type semiconductor region includes a first peripheral region closer to the second N-type semiconductor region and a second peripheral region farther from the second N-type semiconductor region, and
the P-type semiconductor region includes a surrounding P-type semiconductor region provided in at least a part of each of the first and second peripheral regions in such a manner as to surround the first N-type semiconductor region in a plan view.

### (Appendix 5)

The semiconductor device according to Appendix 4, wherein
the surrounding P-type semiconductor region includes a completely surrounding P-type semiconductor region surrounding a periphery of the first N-type semiconductor region without a gap in a plan view.

### (Appendix 6)

The semiconductor device according to Appendix 4, wherein
the surrounding P-type semiconductor region includes a first partially surrounding P-type semiconductor region provided in at least a part of the first peripheral region and a second partially surrounding P-type semiconductor region provided in at least a part of the second peripheral region,
the first and second partially surrounding P-type semiconductor regions are provided separately from each other,
the first voltage is applied to the first partially surrounding P-type semiconductor region, and
a third voltage lower than the second voltage is applied to the second partially surrounding P-type semiconductor region.

### (Appendix 7)

The semiconductor device according to Appendix 6, wherein
at least one partially surrounding P-type semiconductor region of the first partially surrounding P-type semiconductor region and the second partially surrounding P-type semiconductor region includes a P-type semiconductor region group for partial surrounding composed of a plurality of P-type partial semiconductor regions provided separately from each other,
the semiconductor device further comprises:
a relay interconnect line electrically connected to each of the plurality of P-type partial semiconductor regions, and
the first voltage or the third voltage is applied to the P-type semiconductor region group for partial surrounding through the relay interconnect line.

### (Appendix 8)

The semiconductor device according to any one of Appendixes 1 to 7, wherein
the P-type semiconductor region includes a plurality of P-type semiconductor regions provided separately from each other.

### (Appendix 9)

The semiconductor device according to Appendix 8, wherein
the plurality of P-type semiconductor regions includes a first P-type semiconductor region and a second P-type semiconductor region, and
the first voltage is applied commonly to the first and second P-type semiconductor regions.

### (Appendix 10)

The semiconductor device according to Appendix 8, wherein
the plurality of P-type semiconductor regions includes a first P-type semiconductor region and a second P-type semiconductor region,
the first voltage is applied to the first P-type semiconductor region,
a fourth voltage lower than the second voltage is applied to the second P-type semiconductor region, and
the first voltage and the fourth voltage are independent of each other.

### (Appendix 11)

The semiconductor device according any one of Appendixes 1 to 10, wherein
the N-type high-potential region has a surface provided with a first electrode for a high-potential side power supply voltage, and a second electrode for a high-potential region reference voltage, and
the semiconductor device further comprises:
a charging element having one electrode electrically connected to the first electrode of the N-type high-potential region, and the other electrode electrically connected to the second electrode of the N-type high-potential region.

### (Appendix 12)

The semiconductor device according any one of Appendixes 1 to 11, wherein
the first and second N-type semiconductor regions and the P-type semiconductor region are each arranged in such a manner as to surround half or more of an outer perimeter of the N-type high-potential region in a plan view.

While the disclosure has been shown and described in detail, the foregoing description is in all aspects illustrative and not restrictive. It is therefore understood that numerous modifications and variations can be devised.

What is claimed is:

1. A semiconductor device comprising:
a P-type semiconductor layer;
an N-type high-potential region provided on the P-type semiconductor layer;
an N-type high-breakdown voltage isolation region provided on the P-type semiconductor layer in such a manner as to surround the N-type high-potential region in a plan view;
a diode region provided on the P-type semiconductor layer independently of the N-type high-breakdown voltage isolation region, and including a diode with an anode to be supplied with a second voltage higher than a first voltage;
a first N-type semiconductor region and a second N-type semiconductor region provided selectively in an upper layer part of the N-type high-breakdown voltage isolation region; and
a P-type semiconductor region provided selectively in the upper layer part of the N-type high-breakdown voltage isolation region and to be supplied with the first voltage lower than the second voltage, wherein
an N-type impurity concentration in each of the first and second N-type semiconductor regions is set higher than an N-type impurity concentration in the N-type high-breakdown voltage isolation region, the first and second N-type semiconductor regions and the P-type semiconductor region are provided in the absence of contact relationship therebetween,
the second N-type semiconductor region is arranged closer to the N-type high-potential region than the first N-type semiconductor region and the P-type semiconductor region,
the P-type semiconductor region is arranged between the first N-type semiconductor region and the N-type high-potential region in a plan view,
the diode has a cathode electrically connected to the first N-type semiconductor region, and
the second N-type semiconductor region is electrically connected to the N-type high-potential region.

2. The semiconductor device according to claim 1, wherein
the N-type high-potential region has a polygonal shape having three or more corners in a plan view,
the first N-type semiconductor region includes a first N-type parallel region parallel to at least one side of the N-type high-potential region in a plan view,
the second N-type semiconductor region includes a second N-type parallel region parallel to the at least one side of the N-type high-potential region in a plan view,
the P-type semiconductor region includes a P-type parallel region parallel to the at least one side of the N-type high-potential region in a plan view, and
the P-type parallel region is arranged between the first N-type parallel region and the second N-type parallel region in a plan view.

3. The semiconductor device according to claim 1, wherein
the P-type semiconductor region includes a P-type semiconductor region group composed of a plurality of P-type partial semiconductor regions provided separately from each other,
the semiconductor device further comprises:
a relay interconnect line electrically connected to each of the plurality of P-type partial semiconductor regions, and
the first voltage is applied to each of the plurality of P-type partial semiconductor regions of the P-type semiconductor region group through the relay interconnect line.

4. The semiconductor device according to claim 1, wherein
in the N-type high-breakdown voltage isolation region, a peripheral region of the first N-type semiconductor region includes a first peripheral region closer to the second N-type semiconductor region and a second peripheral region farther from the second N-type semiconductor region, and
the P-type semiconductor region includes a surrounding P-type semiconductor region provided in at least a part of each of the first and second peripheral regions in such a manner as to surround the first N-type semiconductor region in a plan view.

5. The semiconductor device according to claim 4, wherein
the surrounding P-type semiconductor region includes a completely surrounding P-type semiconductor region surrounding a periphery of the first N-type semiconductor region without a gap in a plan view.

6. The semiconductor device according to claim 4, wherein
the surrounding P-type semiconductor region includes a first partially surrounding P-type semiconductor region provided in at least a part of the first peripheral region and a second partially surrounding P-type semiconductor region provided in at least a part of the second peripheral region,
the first and second partially surrounding P-type semiconductor regions are provided separately from each other,
the first voltage is applied to the first partially surrounding P-type semiconductor region, and
a third voltage lower than the second voltage is applied to the second partially surrounding P-type semiconductor region.

7. The semiconductor device according to claim 6, wherein
at least one partially surrounding P-type semiconductor region of the first partially surrounding P-type semiconductor region and the second partially surrounding P-type semiconductor region includes a P-type semiconductor region group for partial surrounding composed of a plurality of P-type partial semiconductor regions provided separately from each other,
the semiconductor device further comprises:
a relay interconnect line electrically connected to each of the plurality of P-type partial semiconductor regions, and
the first voltage or the third voltage is applied to the P-type semiconductor region group for partial surrounding through the relay interconnect line.

8. The semiconductor device according to claim 1, wherein
the P-type semiconductor region includes a plurality of P-type semiconductor regions provided separately from each other.

9. The semiconductor device according to claim 8, wherein
the plurality of P-type semiconductor regions includes a first P-type semiconductor region and a second P-type semiconductor region, and
the first voltage is applied commonly to the first and second P-type semiconductor regions.

10. The semiconductor device according to claim 8, wherein
the plurality of P-type semiconductor regions includes a first P-type semiconductor region and a second P-type semiconductor region,
the first voltage is applied to the first P-type semiconductor region,
a fourth voltage lower than the second voltage is applied to the second P-type semiconductor region, and
the first voltage and the fourth voltage are independent of each other.

11. The semiconductor device according to claim 1, wherein
the N-type high-potential region has a surface provided with a first electrode for a high-potential side power supply voltage, and a second electrode for a high-potential region reference voltage, and
the semiconductor device further comprises:
a charging element having one electrode electrically connected to the first electrode of the N-type high-potential region, and the other electrode electrically connected to the second electrode of the N-type high-potential region.

12. The semiconductor device according to claim 1, wherein
the first and second N-type semiconductor regions and the P-type semiconductor region are each arranged in such a manner as to surround half or more of an outer perimeter of the N-type high-potential region in a plan view.
